(19) United States
(12) Patent Application Publication
(10) Pub. No.: US 2026/0133488 A1
(43) Pub. Date: May 14, 2026

(54) RADIATION-SENSITIVE COMPOSITION, METHOD FOR FORMING PATTERN, AND ONIUM SALT

(71) Applicant: JSR CORPORATION, Tokyo (JP)

(72) Inventors: Ryuichi NEMOTO, Tokyo (JP); Yudai ABE, Tokyo (JP); Atsuto NISHII, Tokyo (JP); Michihiro MITA, Tokyo (JP); Hajime INAMI, Tokyo (JP); Fuyuki EGAWA, Tokyo (JP)

(73) Assignee: JSR CORPORATION, Tokyo (JP)

(21) Appl. No.: 19/441,079

(22) Filed: Jan. 6, 2026

Related U.S. Application Data
(63) Continuation-in-part of application No. PCT/JP2024/024568, filed on Jul. 8, 2024.

(30) Foreign Application Priority Data
Aug. 7, 2023 (JP) 2023-128515

(51) Int. Cl. G03F 7/004; G03F 7/038; G03F 7/039; G03F 7/20

(52) U.S. Cl. CPC G03F 7/0045; G03F 7/038; G03F 7/039; G03F 7/2006

(57) ABSTRACT

A radiation-sensitive composition includes: an onium salt represented by formula (1); a polymer including a structural unit (I) which includes an acid-dissociable group; and a solvent. Ar¹ is an (a1+b1+1)-valent aromatic ring, Ar² is an (a2+b2+1)-valent aromatic ring, X¹ and X² are each independently a monovalent organic group having 1 to 20 carbon atoms, a cyano group, a nitro group, or a halogen atom, Y¹ is a monovalent organic group having 4 to 20 carbon atoms bonded to Ar¹ through —O—, —S—, or —SO₂—, or a monovalent perfluoroalkyl group having 1 to 20 carbon atoms, and Y² is a monovalent organic group having 4 to 20 carbon atoms bonded to Ar² through —O—, —S—, or —SO₂—, or a monovalent perfluoroalkyl group having 1 to 20 carbon atoms.

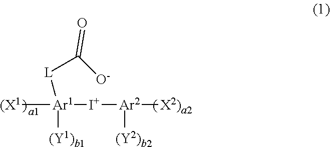

### CROSS-REFERENCE TO RELATED APPLICATIONS

The present application is a continuation-in-part application of International Patent Application No. PCT/JP2024/024568 filed Jul. 8, 2024, which claims priority to Japanese Patent Application No. 2023-128515 filed Aug. 7, 2023. The contents of these applications are incorporated herein by reference in their entirety.

### BACKGROUND OF THE DISCLOSURE

### Technical Field

The present disclosure relates to a radiation-sensitive composition, a method for forming a pattern, and an onium salt.

A photolithography technology using a resist composition has been used for the fine circuit formation in a semiconductor device. As the representative procedure, for example, a resist pattern is formed on a substrate by generating an acid by irradiating the coating of the resist composition with a radioactive ray through a mask pattern, and then reacting in the presence of the acid as a catalyst to generate the difference of solubility of a polymer into an alkaline or organic developer between an exposed part and a non-exposed part.

In the photolithography technique, the micronization of the pattern is promoted by using a short-wavelength radioactive ray such as an ArF excimer laser or by using an immersion exposure method (liquid immersion lithography) in which exposure is performed in a state in which a space between a lens of an exposure apparatus and a resist film is filled with a liquid medium.

As a next-generation technology, lithography using a shorter-wavelength radioactive ray such as an electron beam, an X-ray, and extreme ultraviolet (EUV) is also being studied.

While efforts for further technological development are in progress, a technique has been proposed in which a quencher (acid diffusion controlling agent) is blended in a resist composition, and an acid diffused to a non-exposed part is captured by a salt exchange reaction to improve lithographic performance (JP-B-5706778).

### SUMMARY

According to an aspect of the present disclosure, a radiation-sensitive composition includes: an onium salt represented by formula (1); a polymer including a structural unit (I) which includes an acid-dissociable group; and a solvent.

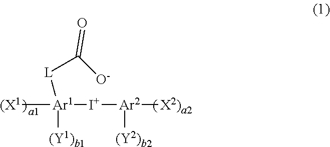

In the formula (1), Ar¹ is an (a1+b1+1)-valent aromatic ring, Ar² is an (a2+b2+1)-valent aromatic ring, X¹ and X² are each independently a monovalent organic group having 1 to 20 carbon atoms, a cyano group, a nitro group, or a halogen atom, when a plurality of X¹s and X²s are present, the plurality of X¹s and X²s are identical to or different from each other, Y¹ is a monovalent organic group having 4 to 20 carbon atoms bonded to Ar¹ through —O—, —S—, or —SO₂—, or a monovalent perfluoroalkyl group having 1 to 20 carbon atoms, when a plurality of Y¹s are present, the plurality of Y¹s are identical to or different from each other, Y² is a monovalent organic group having 4 to 20 carbon atoms bonded to Ar² through —O—, —S—, or —SO₂—, or a monovalent perfluoroalkyl group having 1 to 20 carbon atoms, when a plurality of Y²s are present, the plurality of Y²s are identical to or different from each other,
L is a single bond or a divalent linking group having 1 to 5 carbon atoms, and a1, a2, b1, and b2 are each independently an integer of 0 to 5, provided that when the aromatic ring of Ar² is a benzene ring, b1+b2≥1.

According to another aspect of the present disclosure, a method for forming a pattern includes: directly or indirectly applying the above-described radiation-sensitive composition to a substrate to form a resist film; exposing the resist film to light; and developing the exposed resist film with a developer.

According to a further aspect of the present disclosure, an onium salt is represented by formula (1).

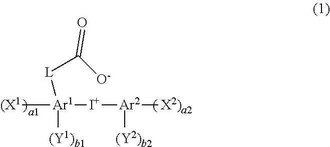

In the formula (1), Ar¹ is an (a1+b1+1)-valent aromatic ring, Ar² is an (a2+b2+1)-valent aromatic ring, X¹ and X² are each independently a monovalent organic group having 1 to 20 carbon atoms, a cyano group, a nitro group, or a halogen atom, when a plurality of X¹s and X²s are present, the plurality of X¹s and X²s are identical to or different from each other, Y¹ is a monovalent organic group having 4 to 20 carbon atoms bonded to Ar¹ through —O—, —S—, or —SO₂—, or a monovalent perfluoroalkyl group having 1 to 20 carbon atoms, when a plurality of Y¹s are present, the plurality of Y¹s are identical to or different from each other, Y² is a monovalent organic group having 4 to 20 carbon atoms bonded to Ar² through —O—, —S—, or —SO₂—, or a monovalent perfluoroalkyl group having 1 to 20 carbon atoms, when a plurality of Y²s are present, the plurality of Y²s are identical to or different from each other, L is a single bond or a divalent linking group having 1 to 5 carbon atoms, and a1, a2, b1, and b2 are each independently an integer of 0 to 5, provided that when the aromatic ring of Ar² is a benzene ring, b1+b2≥1.

### DETAILED DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed.

Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

Among efforts for next-generation technologies, the resist composition is required to have various resist performances equal to or higher than conventional ones in terms of critical dimension uniformity (CDU) performance, depth of focus (DOF) performance, pattern circularity indicating roundness of a hole shape, line width roughness (LWR) performance indicating variation in line width of a resist pattern, pattern rectangularity indicating rectangularity of a cross-sectional shape of a resist pattern, development defect suppression performance, and the like, which are indexes of uniformity of sensitivity, line width,

Since the radiation-sensitive composition of the present disclosure contains the onium salt (1) as a quencher (acid diffusion controlling agent), the radiation-sensitive composition can exhibit various excellent resist performances such as sensitivity, CDU performance, DOF performance, pattern circularity, LWR performance, pattern rectangularity, and development defect suppression performance in pattern formation. Although not bound by any theory, the reason for this can be presumed as follows. The present inventors have considered that the above problem is caused by low solubility of a quencher in a solvent. That is, it is presumed that for a quencher having an intramolecular salt (zwitterion) structure with high polarity, the polarity of the entire structure is also increased, and as a result, the solubility in a solvent is lowered, so that the quencher is not sufficiently dissolved in an organic solvent at the time of organic solvent development, thereby inducing development defects and an increase in roughness. For the onium salt (1), the solubility of the entire molecule in a solvent or a developer can be enhanced by introducing a structure having relatively high hydrophobicity. In addition, since strong basicity is obtained by employing a carboxylate, an excellent quencher function can be exhibited. It is presumed that the radiation-sensitive composition can exhibit the various resist performances at a high level by these synergistic actions.

In the present description, the “organic group” refers to a group containing at least one carbon atom. However, as the organic group, a group that alone becomes a functional group or a characteristic group (cyano group, carboxy group, carbonyl group, and the like) is excluded.

In the pattern formation method of the present disclosure, since the radiation-sensitive composition capable of exhibiting excellent sensitivity, CDU performance, DOF performance, pattern circularity, LWR performance, pattern rectangularity, and development defect suppression performance in pattern formation is used, a high-quality resist pattern can be formed at a high yield.

Since the onium salt (1) can exhibit strong basicity in a resist film together with good solubility in a solvent or a developer, the onium salt (1) is suitable for a radiation-sensitive composition required to have the various resist performances such as development defect suppression performance at a high level.

Hereinafter, embodiments of the present disclosure will be described in detail, but the present disclosure is not limited to these embodiments. Combinations of suitable modes in the embodiments are also preferred.

### <Radiation-Sensitive Composition>

A radiation-sensitive composition (hereinafter, also simply referred to as “composition”) according to the present embodiment contains an onium salt (1), a polymer, and a solvent. The radiation-sensitive composition further contains a radiation-sensitive acid generator, as necessary. The composition may contain other optional components as long as the effects of the present disclosure are not impaired.

### (Onium Salt (1))

The onium salt (1) can function as a quencher (also referred to as a “photodegradable base” or “acid diffusion controlling agent”) that captures acid before exposure or acid in a non-exposed part. The onium salt (1) is represented by the above formula (1).

The aromatic ring represented by Ar¹ and Ar² is not particularly limited as long as the aromatic ring is a ring structure having aromaticity. Examples of the aromatic ring include aromatic hydrocarbon rings such as a benzene ring, a naphthalene ring, an anthracene ring, a phenalene ring, a phenanthrene ring, a pyrene ring, a fluorene ring, a perylene ring, and a coronene ring; aromatic heterocycles such as a furan ring, a pyrrole ring, a thiophene ring, a phosphole ring, a pyrazole ring, an oxazole ring, an isoxazole ring, a thiazole ring, a pyridine ring, a pyrazine ring, a pyrimidine ring, a pyridazine ring, a triazine group, a carbazole ring, and a dibenzofuran ring, or combinations thereof. Among them, as the aromatic ring, a benzene ring, a naphthalene ring, and an anthracene ring are preferable, a benzene ring and a naphthalene ring are more preferable, and a benzene ring is still more preferable. Ar¹ is a group obtained by removing (a1+b1+1) hydrogen atoms from the aromatic ring. Ar² is a group obtained by removing (a2+b2+1) hydrogen atoms from the aromatic ring.

Not only the aromatic ring but also the combination form of the ring structure is not particularly limited. The combination form of the ring structure may be any of a fused ring in which two adjacent rings share one side (two adjacent atoms), an assembled ring in which two adjacent rings are bonded by a single bond, a spiro ring in which two adjacent rings share one carbon atom, and a bridged ring in which two adjacent rings share three or more continuous atoms.

The monovalent organic group having 1 to 20 carbon atoms represented by X¹ and X² is not particularly limited, and examples thereof include a monovalent hydrocarbon group having 1 to 20 carbon atoms, a group (hereinafter, also referred to as a “group (α)”) containing —CO—, —CS—, —O—, —S—, —SO₂—, —NR′— or a combination of two or more thereof at a carbon-carbon position on the hydrocarbon group or at a terminal of the hydrocarbon group, a group (hereinafter, also referred to as a “group (β)”) obtained by substituting some or all of hydrogen atoms contained in the hydrocarbon group or the group (α) with a substituent, or a combination thereof. R′ is a hydrogen atom or a monovalent hydrocarbon group having 1 to 10 carbon atoms. However, X¹ and X² exclude structures corresponding to Y¹ and Y².

Examples of the monovalent hydrocarbon group having 1 to 20 carbon atoms include a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, or a combination thereof.

Examples of the monovalent chain hydrocarbon group having 1 to 20 carbon atoms may include a linear or branched saturated chain hydrocarbon group having 1 to 20 carbon atoms or a linear or branched unsaturated chain hydrocarbon group having 1 to 20 carbon atoms.

Examples of the monovalent alicyclic hydrocarbon group having 3 to 20 carbon atoms include a monocyclic or polycyclic saturated hydrocarbon group or a monocyclic or polycyclic unsaturated hydrocarbon group. As the monocyclic saturated hydrocarbon group, a cyclopentyl group, a cyclohexyl group, a cycloheptyl group, and a cyclooctyl group are preferable. As the polycyclic cycloalkyl group, bridged alicyclic hydrocarbon groups such as a norbornyl group, an adamantyl group, a tricyclodecyl group, and a tetracyclododecyl group are preferable. Examples of the monocyclic unsaturated hydrocarbon group include monocyclic cycloalkenyl groups such as a cyclopropenyl group, a cyclobutenyl group, a cyclopentenyl group, and a cyclohexenyl group. Examples of the polycyclic unsaturated hydrocarbon group include polycyclic cycloalkenyl groups such as a norbornenyl group, a tricyclodecenyl group, and a tetracyclododecenyl group.

Examples of the monovalent aromatic hydrocarbon group having 6 to 20 carbon atoms include aryl groups such as a phenyl group, a tolyl group, a xylyl group, a naphthyl group, and an anthryl group; and aralkyl groups such as a benzyl group, a phenethyl group, and a naphthylmethyl

The group (α) is also suitably a group containing a heterocyclic group containing a hetero atom between carbon atoms constituting a ring. Examples of the heterocyclic group include a group obtained by removing one hydrogen atom from an aromatic heterocyclic structure, a group obtained by removing one hydrogen atom from an aliphatic heterocyclic structure, and a group obtained by combining these groups. Examples of the heteroatom include an oxygen atom, a nitrogen atom, and a sulfur atom.

Examples of the aromatic heterocyclic structure include:
oxygen atom-containing aromatic heterocyclic structures such as furan, benzofuran, and dibenzofuran;
nitrogen atom-containing aromatic heterocyclic structures such as pyrrole, imidazole, pyridine, pyrimidine, pyrazine, indole, quinoline, isoquinoline, acridine, phenazine, and carbazole;
sulfur atom-containing aromatic heterocyclic structures such as thiophene, benzothiophene, and dibenzothiophene; and
aromatic heterocyclic structures containing a plurality of heteroatoms such as thiazole, benzothiazole, thiazine, and oxazine.

Examples of the aliphatic heterocyclic structure include:
oxygen atom-containing aliphatic heterocyclic structures such as oxirane, tetrahydrofuran, tetrahydropyran, dioxolane, and dioxane;
nitrogen atom-containing aliphatic heterocyclic structures such as aziridine, pyrrolidine, piperidine, and piperazine;
sulfur atom-containing aliphatic heterocyclic structures such as thietane, thiolane, and thiane; and
aliphatic heterocyclic structures containing a plurality of heteroatoms, such as morpholine, 1,2-oxathiolane, and 1,3-oxathiolane.

Examples of the aliphatic heterocyclic structure also include a lactone structure, a cyclic carbonate structure, a sultone structure, and a structure containing a cyclic acetal. Examples of such structures include structures represented by formulas (H-1) to (H-11).

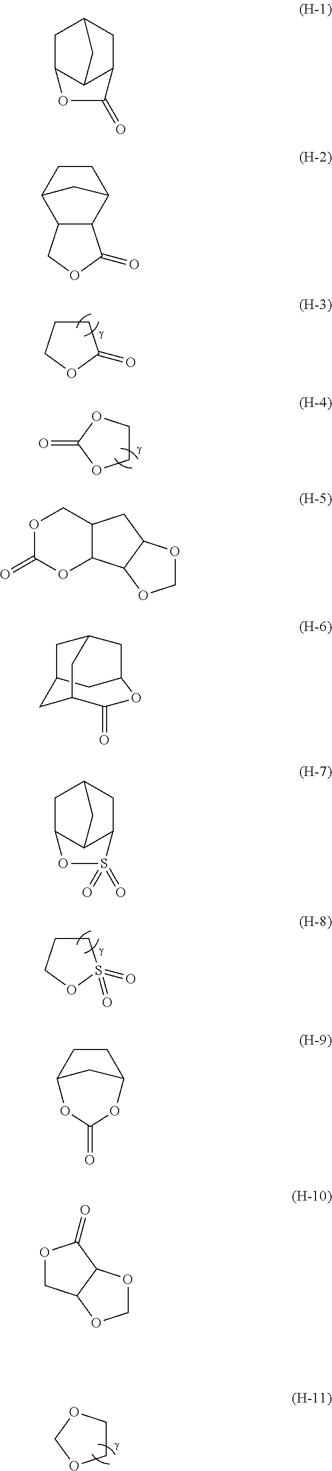

In the formulas, Y is an integer of 1 to 3.

Examples of the substituent that substitutes some or all of the hydrogen atoms of the organic group include a halogen atom such as a fluorine atom, a chlorine atom, a bromine atom, or an iodine atom; a hydroxy group; a carboxy group; a cyano group; a nitro group; an alkyl group; an alkoxy group; an alkoxycarbonyl group; an alkoxycarbonyloxy group; an acyl group; an acyloxy group, or groups obtained by substituting a hydrogen atom on these groups with a halogen atom; and an oxo group (═O).

Examples of the halogen atom represented by X¹ and X² include a fluorine atom, a chlorine atom, a bromine atom, and an iodine atom.

X¹ and X² are preferably a monovalent hydrocarbon group having 1 to 10 carbon atoms, a group containing —O—, —CO—, or a combination thereof at a carbon-carbon position on the hydrocarbon group or at a terminal of the hydrocarbon group, a group obtained by substituting a hydrogen atom on the hydrocarbon group with a fluorine atom, or a halogen atom.

As the monovalent organic group having 4 to 20 carbon atoms in Y¹ and Y², groups corresponding to those having 4 to 20 carbon atoms among the monovalent organic groups having 1 to 20 carbon atoms represented by X¹ and X² can be suitably employed. When the monovalent organic group having 4 to 20 carbon atoms in Y¹ and Y² is represented as y, Y¹ and Y² are each independently represented by the following formula.

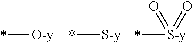

(In the formula, * is a bond to Ar¹ or Ar².)

Y¹ is preferably a monovalent organic group having 4 to 20 carbon atoms bonded to Ar¹ through —O—, or a monovalent perfluoroalkyl group having 1 to 20 carbon atoms, and Y² is preferably a monovalent organic group having 4 to 20 carbon atoms bonded to Ar² through —O—, or a monovalent perfluoroalkyl group having 1 to 20 carbon atoms.

The lower limit of the number of carbon atoms in the monovalent organic group of Y¹ and Y² is preferably 5, more preferably 6, still more preferably 7. The upper limit of the number of carbon atoms is preferably 16, more preferably 12, still more preferably 10. Thus, the onium salt (1) can exhibit good solubility.

The monovalent perfluoroalkyl group having 1 to 20 carbon atoms represented by Y¹ and Y² may be linear or branched, and examples thereof include a trifluoromethyl group, a perfluoroethyl group, a perfluoro-n-propyl group, a perfluoro-i-propyl group, a perfluoro-n-butyl group, a perfluoro-i-butyl group, a perfluoro-t-butyl group, a perfluoro-n-pentyl group, and a perfluoro-n-hexyl group.

As the monovalent perfluoroalkyl group having 1 to 20 carbon atoms represented by Y¹ and Y², a monovalent perfluoroalkyl group having 1 to 10 carbon atoms is preferable, a monovalent linear perfluoroalkyl group having 1 to 5 carbon atoms is more preferable, and a trifluoromethyl group and a perfluoroethyl group are still more preferable.

As the divalent linking group having 1 to 5 carbon atoms represented by L, a group obtained by removing one hydrogen atom from a group corresponding to that having 1 to 5 carbon atoms among the monovalent organic groups having 1 to 20 carbon atoms represented by X¹ and X² can be suitably employed.

L is preferably a single bond or an alkanediyl group having 1 to 3 carbon atoms, more preferably a single bond, a methanediyl group, or an ethanediyl group, still more preferably a single bond. From the viewpoint of basicity of the onium salt (1), L is preferably bonded to an ortho position of a carbon atom to which I⁺ in the formula (1) is bonded.

a1, a2, b1, and b2 are each independently preferably an integer of 0 to 4, more preferably an integer of 0 to 3, still more preferably an integer of 0 to 2.

When the aromatic ring of Ar² is a benzene ring, 1≤b1+b2≤3 is preferable, 1≤b1+b2≤2 is more preferable, and b1+b2=1 is still more preferable. Among them, it is preferable that b1 be 0 and b2 satisfy the above range, and it is more preferable that b1 be 0 and b2 be 1.

The onium salt is preferably represented by formula (1-1), (1-2), or (1-3).

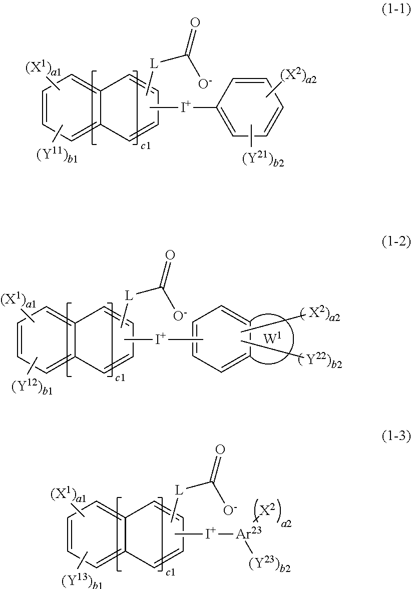

(In the formula (1-1), X¹, X², L, a1, a2, b1, and b2 have the same meaning as in the formula (1). Y¹¹ and Y²¹ are each independently a monovalent organic group having 4 to 20 carbon atoms bonded to each aromatic ring in the formula (1-1) through —O—, —S—, or —SO₂—, or a monovalent perfluoroalkyl group having 1 to 20 carbon atoms. c1 is 0 or 1.

In the formula (1-2), X¹, X², L, a1, and a2 have the same meaning as in the formula (1). W¹ is an alicyclic hydrocarbon structure, an aromatic hydrocarbon structure, or an aliphatic heterocyclic structure each forming a fused ring with an adjacent benzene ring in the formula (1-2). Y¹² and Y²² are each independently a monovalent organic group having 4 to 20 carbon atoms bonded to each aromatic ring in the formula (1-2) through —O—, —S—, or —SO₂—, or a monovalent perfluoroalkyl group having 1 to 20 carbon atoms. b1 and b2 are each independently an integer of 0 to 5. c1 is 0 or 1.

In the formula (1-3), L, X¹, X², a1, and a2 have the same meaning as in the formula (1). Ar²³ is an aromatic heterocyclic ring. Y¹³ is a monovalent organic group having 4 to 20 carbon atoms bonded to an aromatic ring in the formula (1-3) through —O—, —S—, or —SO₂—, or a monovalent perfluoroalkyl group having 1 to 20 carbon atoms. Y²³ is a monovalent organic group having 4 to 20 carbon atoms bonded to Ar²³ through —O—, —S—, or —SO₂—, or a monovalent perfluoroalkyl group having 1 to 20 carbon atoms. b1 and b2 are each independently an integer of 0 to 5. c1 is 0 or 1.)

In the formula (1-1), as the monovalent organic group having 4 to 20 carbon atoms represented by Y¹¹ and Y²¹ and bonded to each aromatic ring in the formula (1-1) through —O—, —S—, or —SO₂—, a monovalent organic group having 4 to 20 carbon atoms represented by Y¹ in the formula (1) and bonded to Ar¹ through —O—, —S—, or —SO₂— and a monovalent organic group having 4 to 20 carbon atoms represented by Y² and bonded to Ar² through —O—, —S—, or —SO₂— can be suitably employed. Similarly, also as the monovalent organic group represented by Y¹² and Y²² in the formula (1-2) and the monovalent organic group represented by Y¹³ and Y²³ in the formula (1-3), a monovalent organic group having 4 to 20 carbon atoms bonded to Ar¹ represented by Y¹ in the formula (1) through —O—, —S—, or —SO₂— and a monovalent organic group having 4 to 20 carbon atoms bonded to Ar² represented by Y² through —O—, —S—, or —SO₂— can be suitably employed, respectively.

In the formula (1-1), as the monovalent perfluoroalkyl group having 1 to 20 carbon atoms represented by Y¹¹ and Y²¹, monovalent perfluoroalkyl groups having 1 to 20 carbon atoms represented by Y¹ and Y² in the formula (1) can be suitably employed. Similarly, also as the monovalent perfluoroalkyl group represented by Y¹² and Y²² in the formula (1-2) and the monovalent perfluoroalkyl group represented by Y¹³ and Y²³ in the formula (1-3), monovalent perfluoroalkyl groups represented by Y¹ and Y² in the formula (1) can be suitably employed, respectively.

In the formulas (1-1) to (1-3), c1 is preferably 0.

In the formula (1-2), as the alicyclic hydrocarbon structure, the aromatic hydrocarbon structure, and the aliphatic heterocyclic structure that form a fused ring with an adjacent benzene ring in the formula (1-2) represented by W¹, a structure corresponding to the monovalent alicyclic hydrocarbon group having 3 to 20 carbon atoms in X¹ and X² in the formula (1), a structure corresponding to the monovalent aromatic hydrocarbon group having 6 to 20 carbon atoms in X¹ and X² in the formula (1), and the aliphatic heterocyclic structure in X¹ and X² in the formula (1) can be suitably employed, respectively. Even when W¹ is an alicyclic hydrocarbon structure or an aliphatic heterocyclic structure, the fused ring of the benzene ring and W¹ is contained in the aromatic ring of Ar² in the formula (1) because the condensed ring exhibits aromaticity as a whole together with the adjacent benzene ring. When W¹ is an alicyclic hydrocarbon structure or an aliphatic heterocyclic structure, a carbon-carbon bond shared with an adjacent benzene ring is treated as a single bond when W¹ is considered.

In the formula (1-2), the alicyclic hydrocarbon structure represented by W¹ is preferably a cycloalkane structure having 3 to 10 carbon atoms, more preferably a cycloalkane structure having 4 to 7 carbon atoms, still more preferably a cyclopentane structure or a cyclohexane structure.

In the formula (1-2), the aromatic hydrocarbon structure represented by W¹ is preferably an aromatic hydrocarbon structure having 6 to 12 carbon atoms, more preferably a benzene ring structure.

In the formula (1-2), the aliphatic heterocyclic structure represented by W¹ is preferably an aliphatic heterocyclic structure containing an oxygen atom as the ring-constituting atom, more preferably a lactone structure, a cyclic acetal structure, or a cyclic ether structure.

In the formulas (1-2) to (1-3), b1 and b2 are each independently preferably an integer of 0 to 3, more preferably an integer of 0 to 2, still more preferably 0 or 1.

In the formula (1-3), as the aromatic heterocyclic ring represented by Ar²³, the aromatic heterocyclic ring structures in X¹ and X² in the formula (1) can be suitably employed. Among them, Ar²³ is preferably a 5-membered aromatic heterocyclic structure or a ring structure in which a 5-membered aromatic heterocyclic structure and an aromatic hydrocarbon structure are fused.

Specific examples of the onium salt (1) represented by the formula (1) are not particularly limited, and examples thereof include structures represented by formulas (C-1) to (C-72) below.

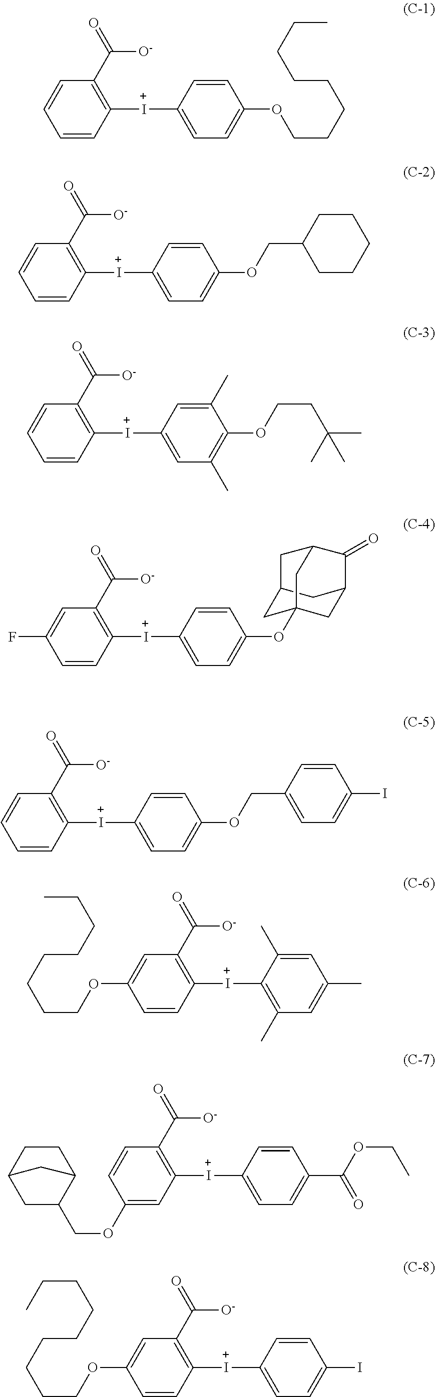

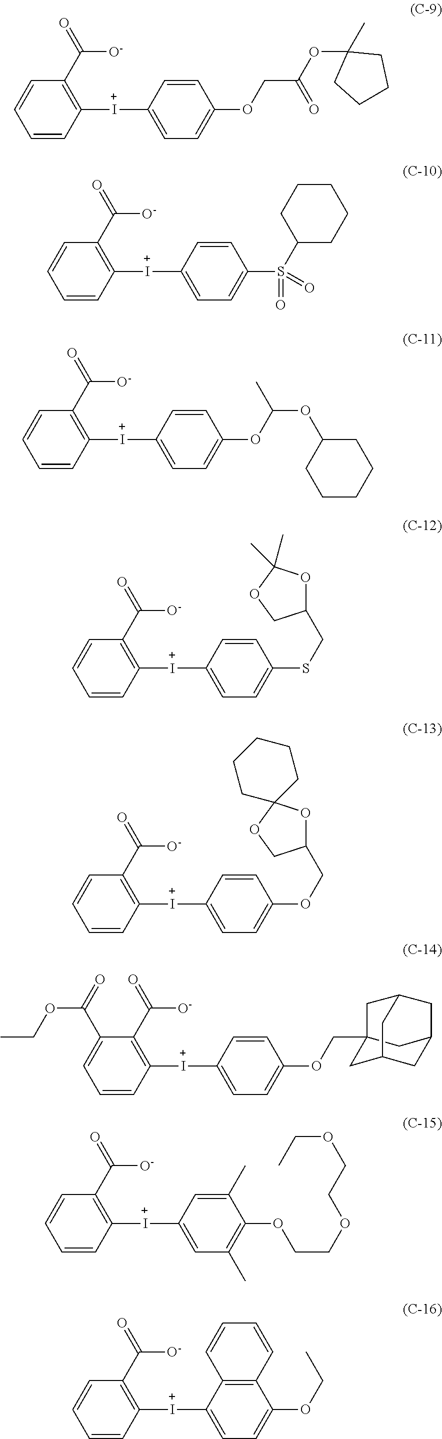

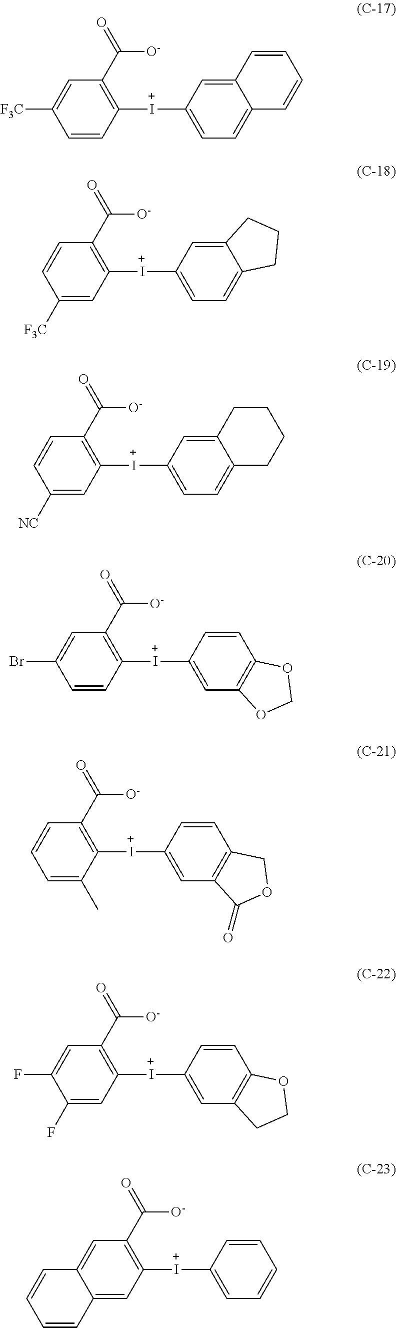

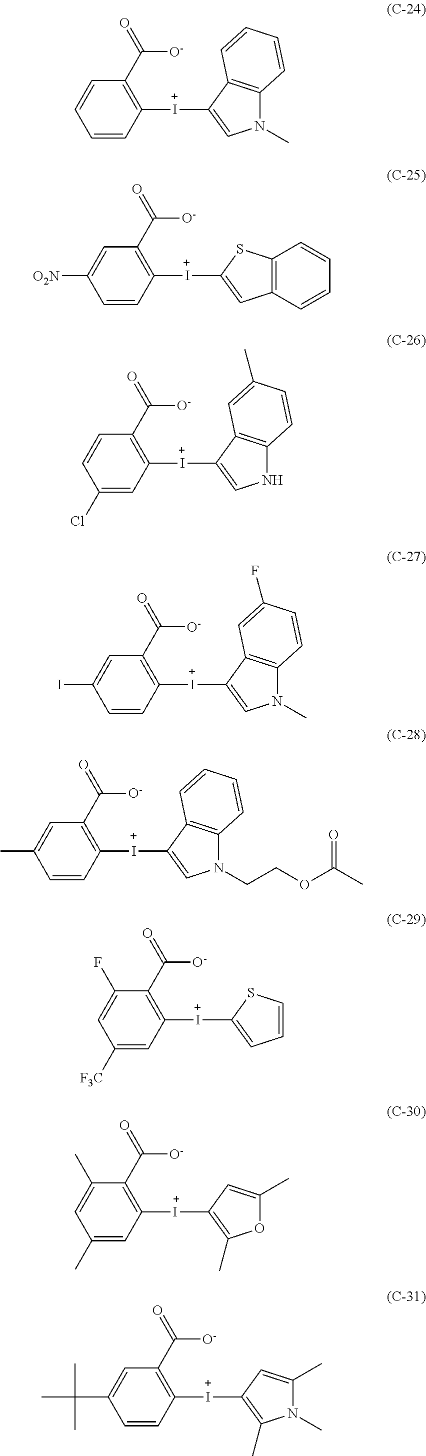

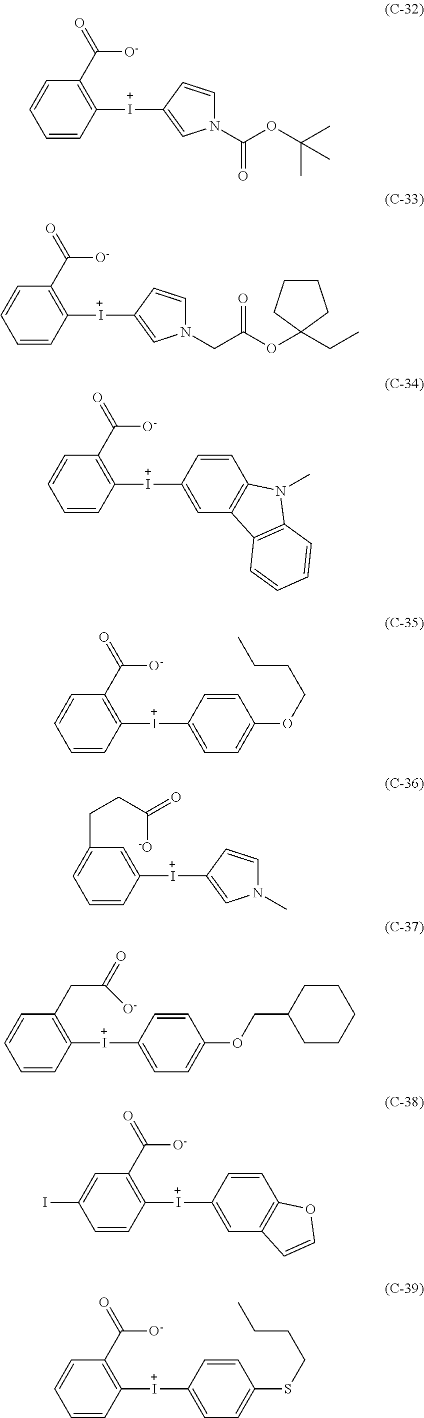

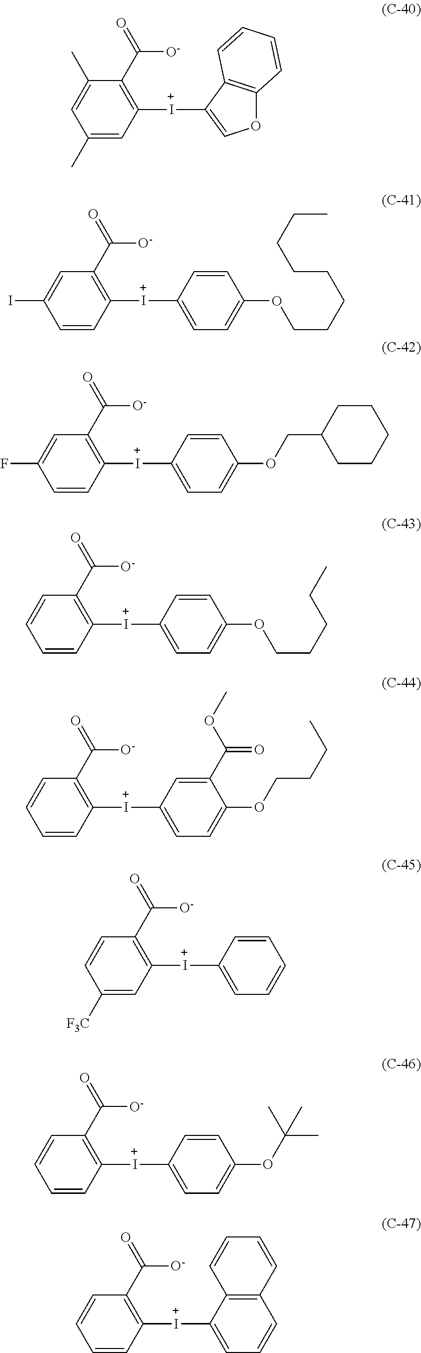

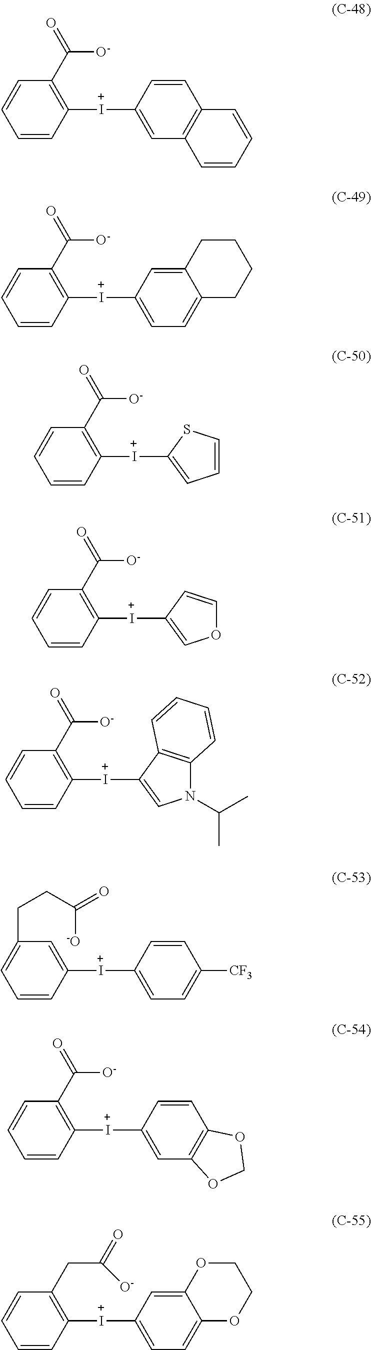

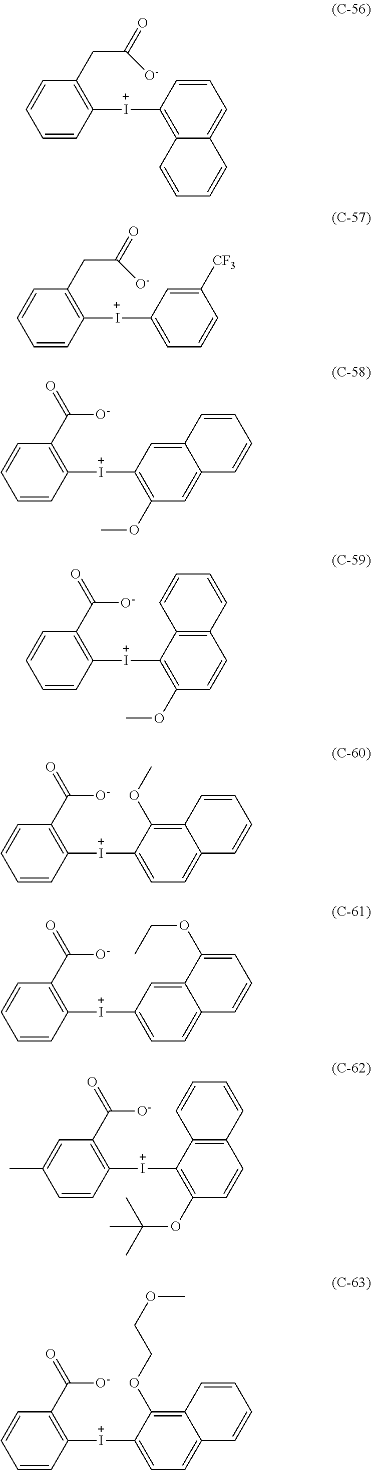

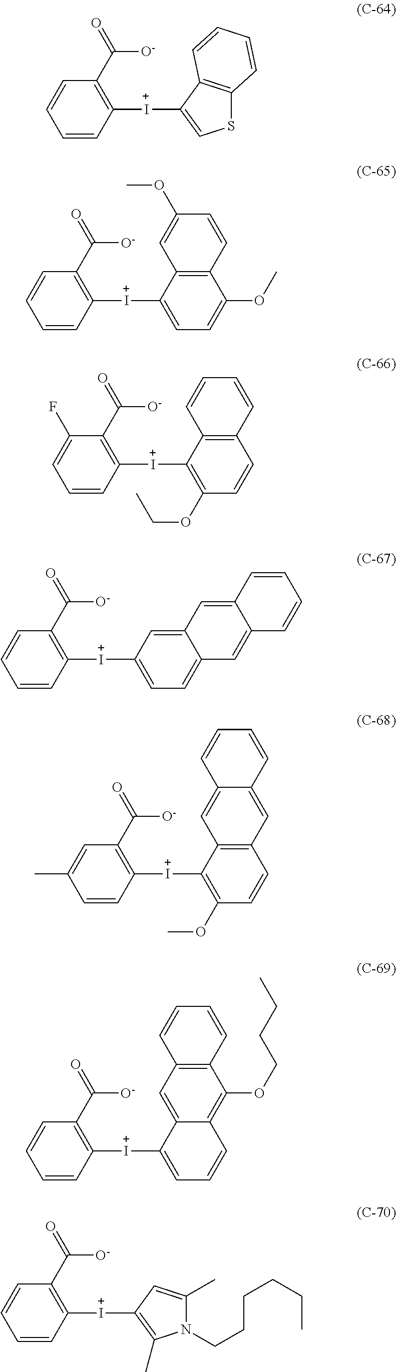

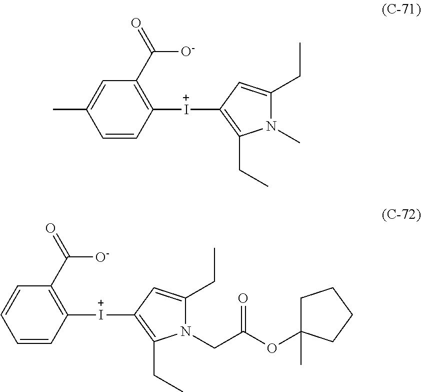 [SMILES: CCc1cc([I+]c2ccc(C)cc2C(=O)[O-])c(CC)n1C ; CCc1cc([I+]c2ccccc2C(=O)[O-])c(CC)n1CC(=O)OC1(C)CCCC1]

The lower limit of the content of the onium salt (1) (in the case of using two or more kinds of onium salts in combination, the total content thereof) is preferably 0.1 parts by mass, more preferably 0.5 parts by mass, still more preferably 1 part by mass, particularly preferably 3 parts by mass, with respect to 100 parts by mass of the polymer described later. The upper limit of the content is preferably 80 parts by mass, more preferably 60 parts by mass, even more preferably 50 parts by mass, and particularly preferably 40 parts by mass. By adjusting the content of the onium salt (1) within the above range, various resist performances described above can be exhibited at the time of forming a resist pattern.

### (Method for Synthesizing Onium Salt (1))

The onium salt (1) can be typically synthesized according to the following scheme. In order to simplify the scheme, a description is made of a case in which Ar¹ and Ar² in the formula (1) are benzene rings, a1, a2, and b1 are 0, and b2 is 1. An onium salt (la) of interest can be synthesized by using, as a raw material, an iodobenzoic acid analog that provides a carboxylate anion of the onium salt (1), reacting the iodobenzoic acid analog with an oxidizing agent followed by a benzene having a predetermined substituent (in the scheme, Y²) in a nucleophilic manner, and finally treating the reactant with a (weak) base. Other structures can also be synthesized by appropriately changing a raw material and a reagent to be reacted therewith.

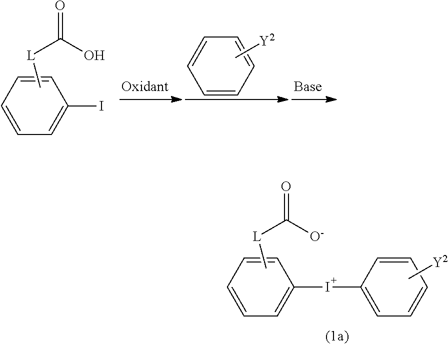

(In the scheme, L and Y² have the same meaning as in the formula (1).)

### (Polymer)

The polymer is an aggregate of polymerization chains having a structural unit (I) containing an acid-dissociable group (hereinafter, this polymer is also referred to as “base polymer”). The “acid-dissociable group” refers to a group that substitutes for a hydrogen atom of a carboxy group, a phenolic hydroxyl group, an alcoholic hydroxyl group, a sulfo group, or the like, and is dissociated by the action of an acid. The radiation-sensitive composition is excellent in pattern-forming performance because the polymer has the structural unit (I).

In addition to the structural unit (I), the base polymer preferably has a structural unit (II) containing at least one selected from the group consisting of a lactone structure, a cyclic carbonate structure, a sultone structure, and a lactam structure described later, and may have another structural unit other than the structural units (I) and (II). Each of the structural units will be described below.

### [Structural Unit (I)]

The structural unit (I) contains an acid-dissociable group. The structural unit (I) is not particularly limited as long as it contains an acid-dissociable group. Examples of such a structural unit (I) include a structural unit having a tertiary alkyl ester moiety, a structural unit having a structure obtained by substituting the hydrogen atom of a phenolic hydroxyl group with a tertiary alkyl group, and a structural unit having an acetal bond. From the viewpoint of improving the pattern-forming performance of the radiation-sensitive composition, a structural unit represented by formula (3) (hereinafter also referred to as a “structural unit (I-1)”) is preferred.

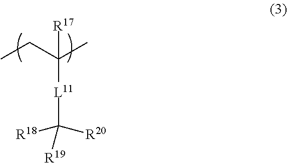

In the above formula (3), R¹⁷ is a hydrogen atom, a fluorine atom, a methyl group, or a trifluoromethyl group. R¹⁸ is a substituted or unsubstituted monovalent hydrocarbon group having 1 to 20 carbon atoms. R¹⁹ and R²⁰ are each independently a substituted or unsubstituted monovalent chain hydrocarbon group having 1 to 10 carbon atoms or a substituted or unsubstituted monovalent alicyclic hydrocarbon group having 3 to 20 carbon atoms, or R¹⁹ and R²⁰ taken together represent a divalent alicyclic group having 3 to 20 carbon atoms together with a carbon atom to which R¹⁹ and R²⁰ are bonded. L¹¹ represents *—COO—, *-L^{11a}COO—, or *—COOL^{11a}COO—. L^{11a} is a substituted or unsubstituted alkanediyl group or arenediyl group. * is a bond to a carbon atom bonded to R¹⁷.

As R¹⁷, from the viewpoint of the copolymerizability of a monomer that affords the structural unit (1-1), a hydrogen atom and a methyl group are preferable, and a methyl group is more preferable.

Examples of the alkanediyl group represented by L^{11a} include alkanediyl groups having 1 to 10 carbon atoms such as a methylene group, an ethanediyl group, a 1,3-propanediyl group, and a 2,2-propanediyl group. L^{11a} is preferably a methylene group or an ethanediyl group.

Examples of the arenediyl group represented by L^{11a} include divalent aromatic hydrocarbon groups having 6 to 20 carbon atoms such as a benzenediyl group and a naphthalenediyl group. L^{11a} is preferably a benzenediyl group.

Examples of the substituent that can be possessed by the arenediyl group represented by L^{11a} include a halogen atom, a hydroxy group, a carboxy group, a cyano group, a nitro group, an alkyl group, a fluorinated alkyl group, an alkoxycarbonyloxy group, an acyl group, an acyloxy group, and an alkoxy group.

Examples of the monovalent hydrocarbon group having 1 to 20 carbon atoms represented by R¹⁸ include a monovalent chain hydrocarbon group having 1 to 10 carbon atoms, a monovalent alicyclic hydrocarbon group having 3 to 20 carbon atoms, and a monovalent aromatic hydrocarbon group having 6 to 20 carbon atoms.

Examples of the monovalent chain hydrocarbon groups having 1 to 10 carbon atoms represented by R¹⁸ to R²⁰ include monovalent linear or branched saturated hydrocarbon groups having 1 to 10 carbon atoms and monovalent linear or branched unsaturated hydrocarbon groups having 1 to 10 carbon atoms.

As the monovalent alicyclic hydrocarbon groups having 3 to 20 carbon atoms represented by R¹⁸ to R²⁰, the monovalent alicyclic hydrocarbon groups having 3 to 20 carbon atoms in X¹ and X² of the above formula (1) can be suitably employed.

As the monovalent aromatic hydrocarbon group having 6 to 20 carbon atoms represented by R¹⁸, the monovalent aromatic hydrocarbon groups having 6 to 20 carbon atoms in X¹ and X² in the above formula (1) can be suitably employed.

As the substituent that can be possessed by the monovalent hydrocarbon group having 1 to 20 carbon atoms represented by the R¹⁸, substituents that can be possessed by monovalent organic groups having 1 to 20 carbon atoms represented by X¹ and X² in the formula (1) can be suitably employed.

R¹⁸ is preferably a linear or branched saturated hydrocarbon group having 1 to 10 carbon atoms or an alicyclic hydrocarbon group having 3 to 20 carbon atoms.

The divalent alicyclic group having 3 to 20 carbon atoms formed by R¹⁹ and R¹⁰ together with the carbon atom to which R¹⁹ and R¹⁰ are bonded is not particularly limited as long as it is a group obtained by removing two hydrogen atoms from the same carbon atom constituting a carbon ring of a monocyclic or polycyclic alicyclic hydrocarbon having the above-described carbon number. The divalent alicyclic group having 3 to 20 carbon atoms may either be a monocyclic hydrocarbon group or a polycyclic hydrocarbon group. The polycyclic hydrocarbon group may either be a bridged alicyclic hydrocarbon group or a condensed alicyclic hydrocarbon group and may either be a saturated hydrocarbon group or an unsaturated hydrocarbon group. It is to be noted that the condensed alicyclic hydrocarbon group refers to a polycyclic alicyclic hydrocarbon group in which two or more alicyclic rings share their sides (bond between two adjacent carbon atoms).

When the monocyclic alicyclic hydrocarbon group is a saturated hydrocarbon group, preferred examples thereof include a cyclopentanediyl group, a cyclohexanediyl group, a cycloheptanediyl group, and a cyclooctanediyl group. When the monocyclic alicyclic hydrocarbon group is an unsaturated hydrocarbon group, preferred examples thereof include a cyclopentenediyl group, a cyclohexenediyl group, a cycloheptenediyl group, a cyclooctenediyl group, and a cyclodecenediyl group. The polycyclic alicyclic hydrocarbon group is preferably a bridged alicyclic saturated hydrocarbon group, and preferred examples thereof include a bicyclo[2.2.1]heptane-2,2-diyl group (norbornane-2,2-diyl group), a bicyclo[2.2.2]octane-2,2-diyl group, and a tricyclo[3.3.1.1^{3,7}]decane-2,2-diyl group (adamantane-2,2-diyl group).

Among them, R¹⁸ is preferably an alkyl group having 1 to 4 carbon atoms, and the alicyclic structure formed by R¹⁹ and R²⁰ combined together and a carbon atom to which they are bonded is preferably a polycyclic or monocyclic cycloalkane structure.

As the substituent that can be possessed by R¹⁸ to R²⁰, a substituent that can be possessed by the arenediyl group represented by L^{11a} can be suitably employed.

Examples of the structural unit (I-1) include structural units represented by formulas (3-1) to (3-15) (hereinafter also referred to as “structural units (I-1-1) to (I-1-15)”).

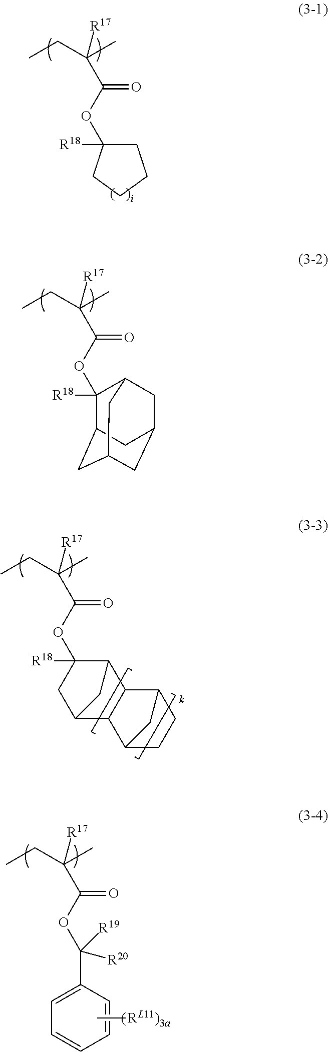

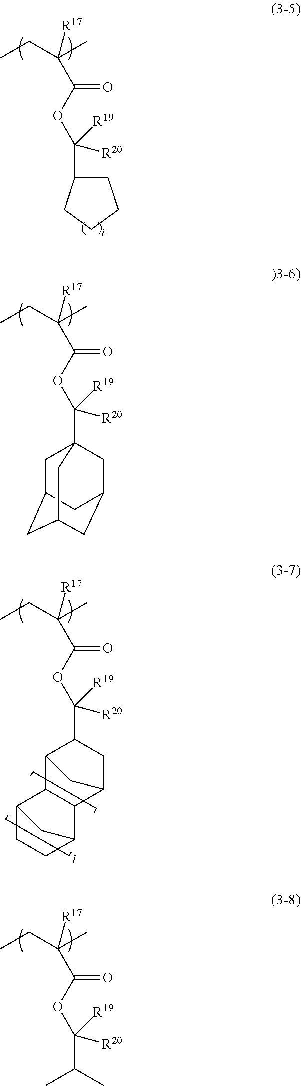

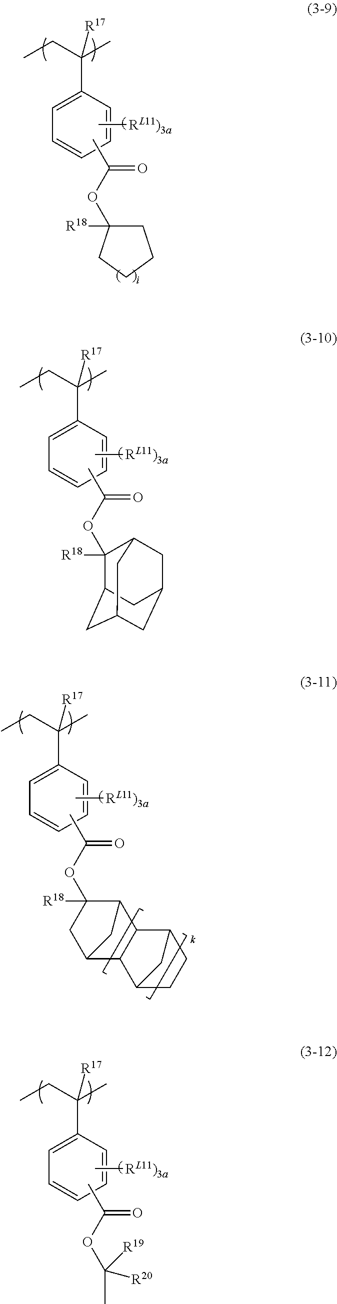

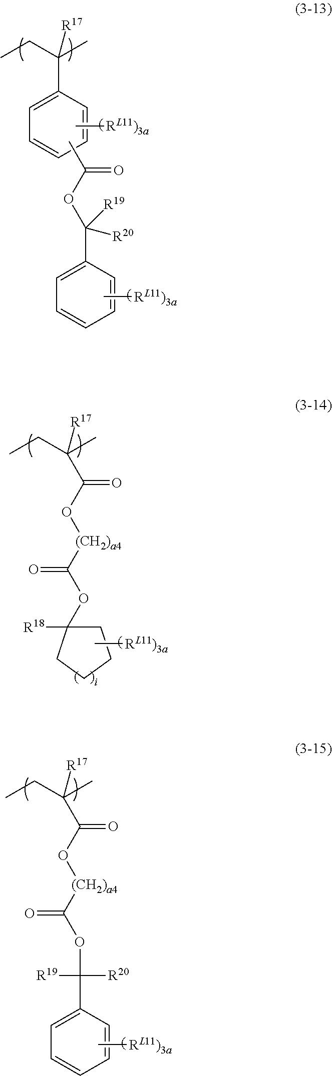

In the above formulas (3-1) to (3-15), R¹⁷ to R²⁰ have the same meaning as in the above formula (3). R^{L11} is a halogen atom, a hydroxy group, a carboxy group, a cyano group, a nitro group, an alkyl group, a fluorinated alkyl group, an alkoxycarbonyloxy group, an acyl group, an acyloxy group, or an alkoxy group; i and j are each independently an integer of 1 to 4. k and l are 0 or 1. 3as are each independently an integer of 0 to 3. When 3a is 2 or more, a plurality of R^{L11}s are the same as or different from each other. a4 is an integer of 1 to 3.

i and j are preferably 1. R¹⁸ is preferably a methyl group, an ethyl group, an isopropyl group, a t-butyl group, an ethenyl group, a phenyl group, or an iodophenyl group. R¹⁹ and R²⁰ are preferably a methyl group, an ethyl group, or an isopropyl group. R^{L11} is preferably an iodine atom, a hydroxy group, or an alkoxy group. By employing an iodine atom as R^{L11}, an iodine group can be suitably introduced into the structural unit (I).

Furthermore, the polymer may contain structural units represented by the following formulas (1f) to (2f) as structural units (I).

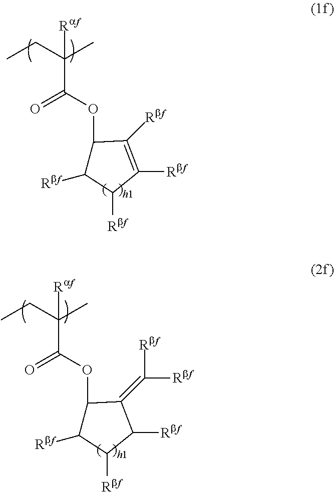

In the formulas (1f) to (2f), R^{αf}s are each independently a hydrogen atom, a fluorine atom, a methyl group, or a trifluoromethyl group. R^{βf}s are each independently a hydrogen atom or a chain alkyl group having 1 to 5 carbon atoms. h1 is an integer of 1 to 4.

As the R^{βf}, a hydrogen atom, a methyl group, or an ethyl group is preferable. h1 is preferably 1 or 2.

The base polymer may contain one type or a combination of two or more types of the structural units (I).

The lower limit of the content (total content, if multiple types are included) of the structural unit (I) is preferably 5 mol %, more preferably 10 mol %, even more preferably 20 mol %, particularly preferably 25 mol % with respect to the total amount of the structural units constituting the base polymer. The upper limit of the content is preferably 80 mol %, more preferably 75 mol %, even more preferably 70 mol %, particularly preferably 65 mol %. When the content of the structural unit (I) is set to fall within the above range, the pattern-forming performance of the radiation-sensitive composition can further be improved.

### [Structural Unit (II)]

The structural unit (II) is a structural unit including at least one selected from the group consisting of a lactone structure, a cyclic carbonate structure, a sultone structure, and a lactam structure. The solubility of the base polymer into a developer can be adjusted by further introducing the structural unit (II). As a result, the radiation-sensitive composition can provide improved lithography properties such as the resolution. The adhesion between a resist pattern formed from the base polymer and a substrate can also be improved.

Examples of the structural unit (II) include structural units represented by formulae (T-1) to (T-11).

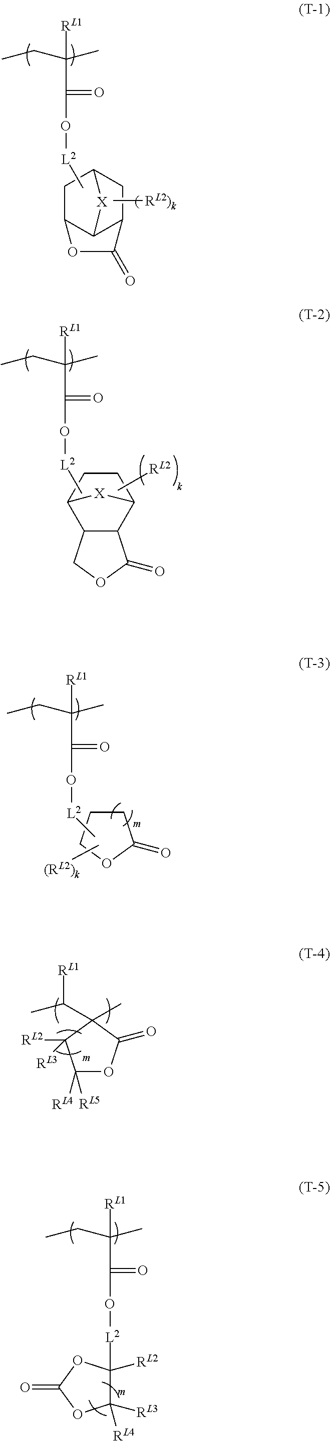

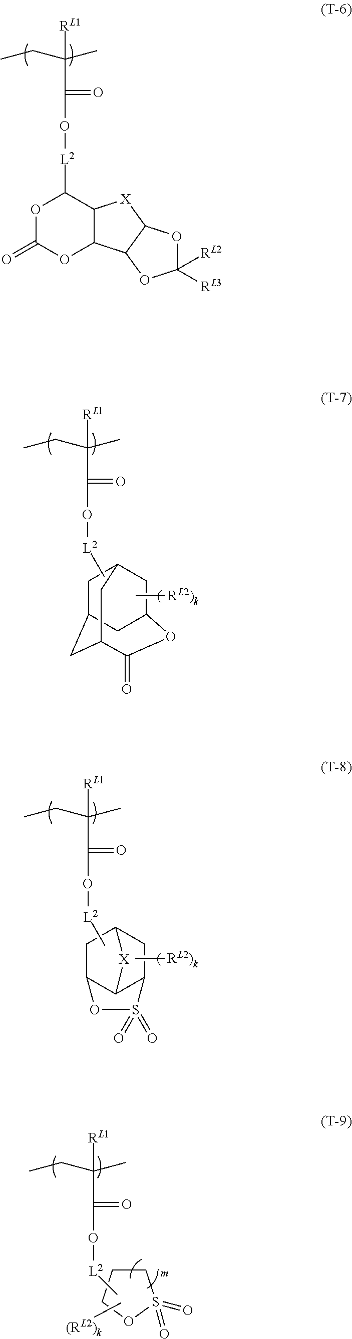

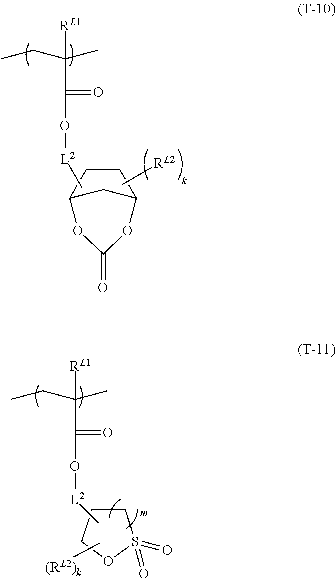

In the above formulae, R^{L1} is a hydrogen atom, a fluorine atom, a methyl group, or a trifluoromethyl group; R^{L2} to R^{L5} are each independently a hydrogen atom, an alkyl group having a carbon number of 1 to 4, a cyano group, a trifluoromethyl group, a methoxy group, a methoxycarbonyl group, a hydroxy group, a hydroxymethyl group, or a dimethylamino group; R^{L4} and R^{L5} may be a divalent alicyclic group having a carbon number of 3 to 8, which is obtained by combining R^{L4} and R^{L5} with the carbon atom to which they are bound. L² is a single bond, or a divalent linking group; X is an oxygen atom or a methylene group; k is an integer of 0 to 3; and m is an integer of 1 to 3.

Examples of the divalent alicyclic group having 3 to 8 carbon atoms in which R^{L4} and R¹⁵ are combined with each other and which is constituted by R^{L4} and R^{L5} together with the carbon atoms to which they are bonded include groups having 3 to 8 carbon atoms among divalent alicyclic groups having 3 to 20 carbon atoms in which R¹⁹ and R²⁰ in the above formula (3) are combined with each other and which is constituted by R¹⁹ and R²⁰ together with the carbon atoms to which they are bonded. One or more hydrogen atoms on the alicyclic group may be substituted with a hydroxy group.

Examples of the divalent linking group represented by L² as described above include a divalent straight or branched chain hydrocarbon group having a carbon number of 1 to 10; a divalent alicyclic hydrocarbon group having a carbon number of 4 to 12; and a group composed of one or more of the hydrocarbon group thereof and at least one group of —CO—, —O—, —NH— and —S—.

Among them, the structural unit (II) is preferably a group having a lactone structure, more preferably a group having a norbornane lactone structure, and further preferably a group derived from a norbornane lactone-yl (meth)acrylate.

The lower limit of the content ratio of the structural unit (II) is preferably 5 mol %, more preferably 10 mol %, and still more preferably 15 mol % with respect to all structural units constituting the base polymer. The upper limit of the content ratio is preferably 80 mol %, more preferably 70 mol %, still more preferably 65 mol %, and particularly preferably 65 mol %. By adjusting the content by percent of the structural unit D within the ranges, the radiation-sensitive composition can provide improved lithography properties such as the resolution. The adhesion between the formed resist pattern and the substrate can also be improved.

### [Structural Unit (III)]

The base polymer optionally has another structural unit in addition to the structural units (I) and (II). Another structural unit includes a structural unit (III) containing a polar group (excluding those corresponding to the structural unit (II)). When the base polymer further has a structural unit (III), solubility in the developer can be adjusted. As a result, lithographic performance such as resolution of the radiation-sensitive composition can be improved. Examples of the polar group include a hydroxy group, a carboxy group, a cyano group, a nitro group, and a sulfonamide group. Among them, a hydroxy group and a carboxy group are preferable, and a hydroxy group is more preferable.

Examples of the structural unit (III) include structural units represented by formulas.

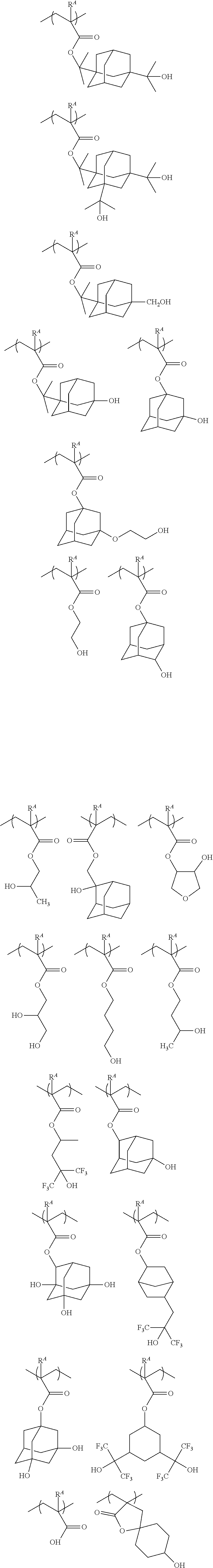

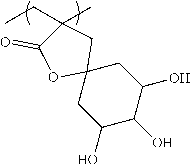

In the above formulas, R^{A} is a hydrogen atom, a fluorine atom, a methyl group, or a trifluoromethyl group.

When the base polymer has the structural unit (III) having a polar group, the lower limit of the content ratio of the structural unit (III) is preferably 1 mol %, more preferably 2 mol %, still more preferably 4 mol % with respect to all structural units constituting the base polymer. The upper limit of the content ratio is preferably 40 mol %, more preferably 30 mol %, and still more preferably 25 mol %. When the content of the structural unit having a polar group is set to fall within the above range, the radiation-sensitive composition can provide further improved lithography properties such as the resolution.

### [Structural Unit (IV)]

The base polymer optionally has, as another structural unit, a structural unit having a phenolic hydroxyl group (hereinafter, also referred to as “structural unit (IV)”), in addition to the structural unit (III) having a polar group. The structural unit (IV) contributes to an improvement in etching resistance and an improvement in a difference in solubility of a developer (dissolution contrast) between an exposed part and a non-exposed part. In particular, the structural unit (IV) can be suitably applied to pattern formation using exposure with a radioactive ray having a wavelength of 50 nm or less, such as an electron beam or EUV. In this case, the polymer preferably has the structural unit (I) together with the structural unit (IV).

The structural unit having a phenolic hydroxyl group is represented by, for example, formulas (4-1) to (4-2).

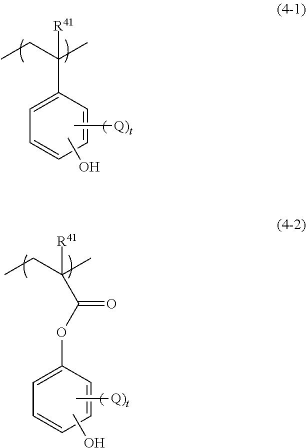

In the above formulas (4-1) to (4-2), R⁴¹ is independently at each occurrence a hydrogen atom, a fluorine atom, a methyl group, or a trifluoromethyl group. Q is each independently a halogen atom, a trifluoromethyl group, a cyano group, an alkyl or alkoxy group having 1 to 6 carbon atoms, or an acyl, acyloxy, or alkoxycarbonyl group having 2 to 7 carbon atoms. When there are a plurality of Q's, the plurality of Q's are the same or different from each other. t is an integer of 0 to 4.

When the structural unit (IV) is obtained, it is preferable that the structural unit (IV) be obtained by performing polymerization in a state where the phenolic hydroxy group of the monomer compound is protected with a protecting group such as an alkali-dissociable group (e.g., an acyl group) during polymerization, and then deprotecting the polymerized product by hydrolysis. It is also possible to perform polymerization without protecting the phenolic hydroxyl group.

In the case of a polymer for exposure with a radioactive ray having a wavelength of 50 nm or less, the lower limit of the content of the structural unit (IV) is preferably 10 mol %, more preferably 20 mol %, with respect to the total amount of structural units constituting the polymer. The upper limit of the content is preferably 70 mol %, more preferably 60 mol %.

### [Other Structural Unit]

The base polymer may contain, as a structural unit other than the structural units listed above, a structural unit represented by a formula (6) below (hereinafter, also referred to as “structural unit (VII)”) and containing an alicyclic structure.

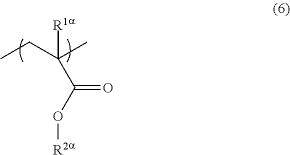

In the formula (6), R^{1α} represents a hydrogen atom, a fluorine atom, a methyl group, or a trifluoromethyl group, and R^{2α} represents a monovalent alicyclic hydrocarbon group having 3 to 20 carbon atoms.

In the formula (6), as the monovalent alicyclic hydrocarbon group having 3 to 20 carbon atoms represented by R^{2α}, the monovalent alicyclic hydrocarbon groups having 3 to 20 carbon atoms represented by X¹ and X² in the above formula (1) can be suitably employed.

When the base polymer contains the structural unit (VII), the lower limit of the content ratio of the structural unit (VII) is preferably 2 mol %, more preferably 5 mol %, still more preferably 8 mol % with respect to all structural units constituting the base polymer. The upper limit of the content is preferably 20 mol %, more preferably 15 mol %, still more preferably 12 mol %.

### (Synthesis Method of Base Polymer)

For example, the base polymer can be synthesized by performing a polymerization reaction of each monomer for providing each structural unit with a radical polymerization initiator or the like in a suitable solvent.

Examples of the radical polymerization initiator include an azo-based radical initiator, including azobisisobutyronitrile (AIBN), 2,2′-azobis(4-methoxy-2,4-dimethylvaleronitrile), 2,2′-azobis(2-cyclopropylpropanenitrile), 2,2′-azobis(2,4-dimethylvaleronitrile), and dimethyl 2,2′-azobisisobutyrate; and peroxide-based radical initiator, including benzoyl peroxide, t-butyl hydroperoxide, and cumene hydroperoxide. Among them, AIBN or dimethyl 2,2′-azobisisobutyrate is preferred, and AIBN is more preferred. The radical initiator may be used alone, or two or more radical initiators may be used in combination.

Examples of the solvent used for the polymerization reaction include
alkanes including n-pentane, n-hexane, n-heptane, n-octane, n-nonane, and n-decane;
cycloalkanes including cyclohexane, cycloheptane, cyclooctane, decalin, and norbornane;
aromatic hydrocarbons including benzene, toluene, xylene, ethylbenzene, and cumene;
halogenated hydrocarbons including chlorobutanes, bromohexanes, dichloroethanes, hexamethylenedibromide, and chlorobenzenes;
saturated carboxylate esters, including ethyl acetate, n-butyl acetate, i-butyl acetate, and methyl propionate;
Included are polyhydric alcohol partial ether acetate-based solvents such as diethylene glycol mono-n-butyl ether acetate, propylene glycol monomethyl ether acetate, and dipropylene glycol monomethyl ether acetate;
ketones such as acetone, methyl ethyl ketone, 2-butanone, 4-methyl-2-pentanone, 2-heptanone, and cyclohexanone;
ethers such as tetrahydrofuran, dimethoxyethane, diethoxyethane, and 1,4-dioxane;
alcohols such as methanol, ethanol, 1-propanol, 2-propanol, 1-methoxy-2-propanol, and 4-methyl-2-pentanol; and
lactones such as γ-butyrolactone. The solvents to be used in the polymerization may be used alone, or two or more thereof may be used in combination.

The reaction temperature of the polymerization reaction is typically from 40° C. to 150° C., and preferably from 50° C. to 120° C. The reaction time is typically from 1 hour to 48 hours, and preferably from 1 hour to 24 hours.

The molecular weight of the base polymer is not particularly limited, but the lower limit of the weight average molecular weight (Mw) as determined by Gel Permeation Chromatography (GPC) relative to standard polystyrene is preferably 2,000, more preferably 3,000, still more preferably 4,000. The upper limit of the Mw is preferably 30,000, more preferably 20,000, and still more preferably 5,000. When the Mw of the base polymer is adjusted in the above range, good heat resistance and developability can be obtained in the resulting resist film.

For the base polymer as a base polymer, the ratio of Mw to the number average molecular weight (Mn) as determined by GPC relative to standard polystyrene (Mw/Mn) is typically not less than 1 and not more than 5, preferably not less than 1 and not more than 3, and more preferably not less than 1 and not more than 2.

The Mw and Mn of the polymer in the specification are amounts measured by using Gel Permeation Chromatography (GPC) with the condition as described below.
GPC column: two G2000HXL, one G3000HXL, and one G4000HXL (all manufactured from Tosoh Corporation)
Column temperature: 40° C.
Eluting solvent: tetrahydrofuran
Flow rate: 1.0 mL/min
Sample concentration: 1.0% by mass
Sample injection amount: 100 μL
Detector: Differential Refractometer
Reference material: monodisperse polystyrene

The content ratio of the base polymer is preferably 50 mass % or more, more preferably 55 mass % or more, and still more preferably 60 mass % or more with respect to the total solid content of the radiation-sensitive composition.

### (Other Polymer)

The radiation-sensitive composition according to the present embodiment may contain, as another polymer, a polymer having a higher content rate by mass of fluorine atoms than the content rate of the base polymer (hereinafter, also referred to as a “higher fluorine-content polymer”). When the radiation-sensitive composition contains the high fluorine-content polymer, the high fluorine-content polymer can be localized in the surface layer of a resist film compared to the base polymer, which as a result makes it possible to enhance the water repellency of the surface of the resist film during immersion exposure or to perform surface modification of the resist film during EUV exposure or control of the distribution of the composition in the film.

The high fluorine-content polymer preferably has, for example, a structural unit represented by formula (5) (hereinafter, also referred to as “structural unit (V)”), and may have the structural unit (I) or the structural unit (III) in the base polymer as necessary.

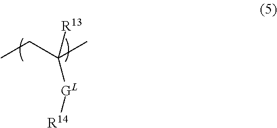

In the above formula (5), R¹³ is a hydrogen atom, a methyl group, or a trifluoromethyl group; G^{L} is a single bond, an alkanediyl group having 1 to 5 carbon atoms, an oxygen atom, a sulfur atom, —COO—, —SO₂ONH—, —CONH—, —OCONH—, or a combination thereof. R¹⁴ is a monovalent fluorinated chain hydrocarbon group having a carbon number of 1 to 20, or a monovalent fluorinated alicyclic hydrocarbon group having a carbon number of 3 to 20.

As R¹³ as described above, in terms of the copolymerizability of monomers resulting in the structural unit (V), a hydrogen atom or a methyl group is preferred, and a methyl group is more preferred.

As G^{L} as described above, in terms of the copolymerizability of monomers resulting in the structural unit (V), a single bond or —COO— is preferred, and —COO— is more preferred.

Example of the monovalent fluorinated chain hydrocarbon group having a carbon number of 1 to 20 represented by R¹⁴ as described above includes a group in which a part of or all of hydrogen atoms in the straight or branched chain alkyl group having a carbon number of 1 to 20 is/are substituted with a fluorine atom.

Example of the monovalent fluorinated alicyclic hydrocarbon group having a carbon number of 3 to 20 represented by R¹⁴ as described above includes a group in which a part of or all of hydrogen atoms in the monocyclic or polycyclic hydrocarbon group having a carbon number of 3 to 20 is/are substituted with a fluorine atom.

The R¹⁴ as described above is preferably a fluorinated chain hydrocarbon group, more preferably a fluorinated alkyl group, and further preferably 2,2,2-trifluoroethyl group, 2,2,3,3,3-pentafluoropropyl group, 1,1,1,3,3,3-hexafluoropropane-2-yl group and 5,5,5-trifluoro-1,1-diethylpentyl group.

When the high fluorine-content polymer has the structural unit (V), the lower limit of the content ratio of the structural unit (V) is preferably 2 mol %, more preferably 5 mol %, and still more preferably 8 mol % with respect to all structural units constituting the high fluorine-content polymer. The upper limit of the content ratio is preferably 30 mol %, more preferably 20 mol %, and still more preferably 15 mol %. When the content of the structural unit (V) is set to fall within the above range, the content by mass of fluorine atoms of the high fluorine-content polymer can more appropriately be adjusted to further promote the localization of the high fluorine-content polymer in the surface layer of a resist film, as a result, the water repellency of the resist film during immersion exposure can be further improved.

The high fluorine-content polymer may have a fluorine atom-containing structural unit represented by formula (f-2) (hereinafter, also referred to as a “structural unit (VI)”) in addition to or in place of the structural unit (V). When the high fluorine-content polymer has the structural unit (VI), solubility in an alkaline developing solution is improved, and therefore generation of development defects can be prevented.

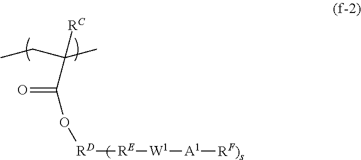

The structural unit (VI) is classified into two groups: a unit having an alkali soluble group (x); and a unit having a group (y) in which the solubility into the alkaline developing solution is increased by the dissociation by alkali (hereinafter, simply referred as an “alkali-dissociable group”). In both cases of (x) and (y), R^{C} in the above formula (f-2) is a hydrogen atom, a fluorine atom, a methyl group, or a trifluoromethyl group; R^{D} is a single bond, a hydrocarbon group having a carbon number of 1 to 20 with the valency of (s+1), a structure in which an oxygen atom, a sulfur atom, —NR^{dd}—, a carbonyl group, —COO—, —OCO—, or —CONH— is connected to the terminal on R^{E} side of the hydrocarbon group, or a structure in which a part of hydrogen atoms in the hydrocarbon group is substituted with an organic group having a hetero atom; R^{dd} is a hydrogen atom, or a monovalent hydrocarbon group having a carbon number of 1 to 10; and s is an integer of 1 to 3.

When the structural unit (VI) has the alkali soluble group (x), R^{F} is a hydrogen atom; A¹ is an oxygen atom, —COO—* or —SO₂O—*; * refers to a bond to R^{F}; W¹ is a single bond, a hydrocarbon group having a carbon number of 1 to 20, or a divalent fluorinated hydrocarbon group. When A¹ is an oxygen atom, W¹ is a fluorinated hydrocarbon group having a fluorine atom or a fluoroalkyl group on the carbon atom connecting to A¹. R^{E} is a single bond, or a divalent organic group having a carbon number of 1 to 20. When s is 2 or 3, a plurality of R^{E}, W¹, A¹ and R^{F} may be each identical or different. The affinity of the high fluorine-content polymer into the alkaline developing solution can be improved by including the structural unit (VI) having the alkali soluble group (x), and thereby prevent from generating the development defect. As the structural unit (VI) having the alkali soluble group (x), particularly preferred is a structural unit in which A¹ is an oxygen atom and W¹ is a 1,1,1,3,3,3-hexafluoro-2,2-methanediyl group.

When the structural unit (VI) has the alkali-dissociable group (y), R^{F} is a monovalent organic group having carbon number of 1 to 30; A¹ is an oxygen atom, —NR^{aa}—, —COO—*, —OCO—*, or —SO₂O—*; R^{aa} is a hydrogen atom, or a monovalent hydrocarbon group having a carbon number of 1 to 10; * refers to a bond to R^{F}; W¹ is a single bond, or a divalent fluorinated hydrocarbon group having a carbon number of 1 to 20; R^{E} is a single bond, or a divalent organic group having a carbon number of 1 to 20. When A¹ is —COO—*, —OCO—*, or —SO₂O—*, W¹ or R^{F} has a fluorine atom on the carbon atom connecting to A¹ or on the carbon atom adjacent to the carbon atom. When A¹ is an oxygen atom, W¹ and R^{E} are a single bond; R^{D} is a structure in which a carbonyl group is connected at the terminal on R^{E} side of the hydrocarbon group having a carbon number of 1 to 20; and R^{F} is an organic group having a fluorine atom. When s is 2 or 3, a plurality of R^{E}, W¹, A¹ and R^{F} may be each identical or different. The surface of the resist film is changed from hydrophobic to hydrophilic in the alkaline developing step by including the structural unit (VI) having the alkali-dissociable group (y). As a result, the affinity of the high fluorine-content polymer into the alkaline developing solution can be significantly improved, and thereby prevent from generating the development defect more efficiently. As the structural unit (VI) having the alkali-dissociable group (y), particularly preferred is a structural unit in which A¹ is —COO—*, and R^{F} or W¹, or both is/are a fluorine atom.

In terms of the copolymerizability of monomers resulting in the structural unit (VI), R^{C} is preferably a hydrogen atom or a methyl group, and more preferably a methyl group.

When the high fluorine-content polymer has the structural unit (VI), the lower limit of the content of the structural unit (VI) is preferably 40 mol %, more preferably 50 mol %, even more preferably 55 mol % with respect to the total amount of all the structural units constituting the high fluorine-content polymer. The upper limit of the content is preferably 90 mol %, more preferably 80 mol %, even more preferably 70 mol %. When the content of the structural unit (VI) is set to fall within the above range, water repellency of a resist film during immersion exposure can further be improved, and the occurrence of development defects can be suppressed.

### [Other Structural Unit]

A high fluorine-content polymer may contain a structural unit having an alicyclic structure represented by the above formula (6) as a structural unit other than the structural units listed above.

When the high fluorine-content polymer contains the structural unit having an alicyclic structure, the content ratio of the structural unit having an alicyclic structure is preferably 10 mol %, more preferably 20 mol %, and still more preferably 30 mol % with respect to all structural units constituting the high fluorine-content polymer. The upper limit of the content ratio is preferably 60 mol %, more preferably 50 mol %, and still more preferably 45 mol %.

The lower limit of the Mw of the high fluorine-content polymer is preferably 3,000, more preferably 5,000, still more preferably 7,000. The upper limit of the Mw is preferably 30,000, more preferably 20,000, still more preferably 12,000.

The lower limit of the Mw/Mn of the high fluorine-content polymer is typically 1, and more preferably 1.1. The upper limit of the Mw/Mn is typically 5, preferably 3, more preferably 2.

When the radiation-sensitive composition contains a high fluorine-content polymer, the lower limit of the content of the high fluorine-content polymer is preferably 0.5 part by mass, more preferably 1 part by mass, further preferably 2 part by mass based on 100 parts by mass of total base polymers. The upper limit of the content is preferably 15 parts by mass, more preferably 10 parts by mass, further preferably 8 parts by mass.

When the content of the high fluorine-content polymer is set to fall within the above range, the high fluorine-content polymer can more effectively be localized in the surface layer of a resist film, which as a result makes it possible to further enhance the water repellency of the surface of the resist film during liquid immersion lithography, and control the surface modification of resist films and the distribution of composition within the film during EUV exposure. The radiation-sensitive composition may contain one kind of high fluorine-content polymer or two or more kinds of high fluorine-content polymers.

### (Method for Synthesizing High Fluorine-Content Polymer)

The high fluorine-content polymer can be synthesized by a method similar to the above-described method for synthesizing a base polymer.

### (Radiation-Sensitive Acid Generator)

The radiation-sensitive composition of the present embodiment preferably further contains a radiation-sensitive acid generator that generates an acid having a pKa lower than that of the acid generated from the onium salt (1) by irradiation (exposure), that is, a relatively strong acid. The acid generated from the radiation-sensitive acid generator by exposure can dissociate the acid-dissociable group of the structural unit (I) in the polymer to generate a carboxy group or the like. This function is different from the function of the onium salt (1) that suppresses the diffusion of the acid generated from the radiation-sensitive acid generator in the non-exposed part without substantially dissociating the acid-dissociable group or the like of the structural unit (I) or the like of the polymer under the pattern formation condition using the radiation-sensitive composition. Each function of the onium salt (1) and the radiation-sensitive acid generator depends on energy required for the dissociation of the acid-dissociable group of the structural unit (I) or the like of the polymer, the acidity of the acid generated from the radiation-sensitive acid generator, and the like. The containing mode of the radiation-sensitive acid generator in the radiation-sensitive composition may be a mode in which the radiation-sensitive acid generator is present alone as a compound (released from a polymer), a mode in which the radiation-sensitive acid generator is incorporated as a part of a polymer, or both of these forms, but a mode in which the radiation-sensitive acid generator is present alone as a compound is preferable.

When the radiation-sensitive composition contains the radiation-sensitive acid generator, the polarity of the polymer in the exposed part increases, whereby the polymer in the exposed part is soluble in the developer in the case of alkaline aqueous solution development, and is poorly soluble in the developer in the case of organic solvent development.

Examples of the radiation-sensitive acid generator include an onium salt (excluding the onium salt (1)), a sulfonimide compound, a halogen-containing compound, and a diazoketone compound. Examples of the onium salt include a sulfonium salt, a tetrahydrothiophenium salt, an iodonium salt, a phosphonium salt, a diazonium salt, and a pyridinium salt. Among them, a sulfonium salt and an iodonium salt are preferable.

Examples of the acid generated during exposure may include sulfonic acid. Examples of the radiation-sensitive acid generator that generates such an acid include a compound in which a carbon atom adjacent to a sulfo group has one or more substituted fluorine atoms or fluorinated hydrocarbon groups. As the radiation-sensitive acid generator, in addition to the radiation-sensitive acid generator having a sulfo group and such a structure on a carbon atom adjacent to the sulfo group, a radiation-sensitive acid generator having a cyclic structure, or a structure in which —O—, —CO—, or two or more thereof are combined is particularly preferable. The cyclic structure is preferably a polycyclic aliphatic hydrocarbon structure or a polycyclic aliphatic heterocyclic structure.

These radiation-sensitive acid generators may be used alone or in combination of two or more thereof. The lower limit of the content of the radiation-sensitive acid generator (the total content in the case of a plurality of radiation-sensitive acid generators) is preferably 2 parts by mass, more preferably 4 parts by mass, and further preferably 6 parts by mass with respect to 100 parts by mass of the base polymer. The upper limit of the content is preferably 60 parts by mass, more preferably 50 parts by mass, and still more preferably 45 parts by mass, based on 100 parts by mass of the base polymer. This makes it possible to exert excellent various resist performances when having a resist pattern formed thereon.

### <Solvent>

The radiation-sensitive composition according to the present embodiment contains a solvent. The solvent is not particularly limited as long as it can dissolve or disperse at least the onium salt (1) and the polymer, and the radiation-sensitive acid generator or the like contained if necessary.

Examples of the solvent include an alcohol-based solvent, an ether-based solvent, a ketone-based solvent, an amide-based solvent, an ester-based solvent, and a hydrocarbon-based solvent.

Examples of the alcohol-based solvent include:
a monoalcohol-based solvent having a carbon number of 1 to 18, including iso-propanol, 4-methyl-2-pentanol, 3-methoxybutanol, n-hexanol, 2-ethylhexanol, furfuryl alcohol, cyclohexanol, 3,3,5-trimethylcyclohexanol, and diacetone alcohol;
a polyhydric alcohol having a carbon number of 2 to 18, including ethylene glycol, 1,2-propylene glycol, 2-methyl-2,4-pentanediol, 2,5-hexanediol, diethylene glycol, dipropylene glycol, triethylene glycol, and tripropylene glycol; and
a partially etherized polyhydric alcohol-based solvent in which a part of hydroxy groups in the polyhydric alcohol-based solvent is etherized.

In the present embodiment, the alcohol-based solvents also include alcohol acid esters such as methyl lactate, ethyl lactate, propyl lactate, butyl lactate, methyl 2-hydroxyisobutyrate, i-propyl 2-hydroxyisobutyrate, i-butyl 2-hydroxyisobutyrate, and n-butyl 2-hydroxyisobutyrate.

Examples of the ether-based solvent include:
a dialkyl ether-based solvent, including diethyl ether, dipropyl ether, and dibutyl ether;
a cyclic ether-based solvent, including tetrahydrofuran and tetrahydropyran;
an ether-based solvent having an aromatic ring, including diphenylether and anisole (methyl phenyl ether); and
an etherized polyhydric alcohol-based solvent in which a hydroxy group in the polyhydric alcohol-based solvent is etherized, including propylene glycol monomethyl ether.

Examples of the ketone-based solvent include:
a chain ketone-based solvent, including acetone, butanone, and methyl-iso-butyl ketone;
a cyclic ketone-based solvent, including cyclopentanone, cyclohexanone, and methylcyclohexanone; and
2,4-pentanedione, acetonylacetone, and acetophenone.

Examples of the amide-based solvent include:
a cyclic amide-based solvent, including N,N′-dimethyl imidazolidinone and N-methylpyrrolidone; and
a chain amide-based solvent, including N-methylformamide, N, N-dimethylformamide, N, N-diethylformamide, acetamide, N-methylacetamide, N, N-dimethylacetamide, and N-methylpropionamide.

Examples of the ester-based solvent include:
a monocarboxylate ester-based solvent, including n-butyl acetate and ethyl lactate;
a partially etherized polyhydric alcohol acetate-based solvent, including diethylene glycol mono-n-butyl ether acetate, propylene glycol monomethyl ether acetate, and dipropylene glycol monomethyl ether acetate;
a lactone-based solvent, including γ-butyrolactone and valerolactone;
a carbonate-based solvent, including diethyl carbonate, ethylene carbonate, and propylene carbonate; and
a polyhydric carboxylic acid diester-based solvent, including propylene glycol diacetate, methoxy triglycol acetate, diethyl oxalate, ethyl acetoacetate, ethyl lactate, and diethyl phthalate.

Examples of the hydrocarbon-based solvent include:
an aliphatic hydrocarbon-based solvent, including n-hexane, cyclohexane, and methylcyclohexane;
an aromatic hydrocarbon-based solvent, including benzene, toluene, di-iso-propylbenzene, and n-amylnaphthalene.

Among these, an alcohol-based solvent and an ester-based solvent are preferable, a polyhydric alcohol partial ether-base solvent, a polyhydric alcohol partial ether acetate-based solvent, a lactone-based solvent, and a monocarboxylic acid ester-based solvent are more preferable, and propylene glycol monomethyl ether, ethyl lactate, propylene glycol monomethyl ether acetate, and γ-butyrolactone are still more preferable. The radiation-sensitive composition may contain one solvent, or two or more solvents.

### <Other Optional Components>

The radiation-sensitive composition may contain other optional components other than the above-descried components. Examples of other optional components include a cross-linking agent, a localization enhancing agent, a surfactant, an alicyclic backbone-containing compound, and a sensitizer. These other optional components may be used singly or in combination of two or more of them. The content of other optional components is usually 5 parts by mass or less based on 100 parts by mass of the polymer.

### <Method for Preparing Radiation-Sensitive Composition>

The radiation-sensitive composition can be prepared by, for example, mixing the onium salt (1), the polymer, and the solvent with the radiation-sensitive acid generator, the high fluorine-content polymer, and the like as necessary at a predetermined ratio. The radiation-sensitive composition is preferably filtered through, for example, a filter having a pore size of about 0.1 μm to 0.5 μm after mixing. The solid matter concentration of the radiation-sensitive composition is usually 0.1 mass % to 50 mass %, preferably 0.5 mass % to 30 mass %, and more preferably 1 mass % to 20 mass %.

### <Method for Forming Pattern>

A pattern forming method according to an embodiment of the present invention includes:
(1) applying the radiation-sensitive composition directly or indirectly on a substrate to form a resist film (hereinafter, also referred to as a “resist film forming step”);
(2) exposing the resist film (hereinafter, also referred to as an “exposure step”); and
(3) developing the exposed resist film with a developer (hereinafter, also referred to as a “developing step”).

The method for forming a pattern uses the above-described radiation-sensitive composition excellent in various resist performances, and therefore a high-quality resist pattern can be efficiently formed. Hereinbelow, each of the steps will be described.

### [Resist Film Forming Step]

In this step (the above mentioned step (1)), a resist film is formed with the radiation-sensitive composition. Examples of the substrate on which the resist film is formed include one traditionally known in the art, including a silicon wafer, silicon dioxide, and a wafer coated with aluminum. An organic or inorganic antireflection film may be formed on the substrate, as disclosed in JP-B-06-12452 and JP-A-59-93448. Examples of the applicating method include a rotary coating (spin coating), flow casting, and roll coating. After applicating, a prebake (PB) may be carried out in order to evaporate the solvent in the film, if needed. The temperature of PB is typically from 60° C. to 150° C., and preferably from 80° C. to 140° C. The duration of PB is typically from 5 seconds to 600 seconds, and preferably from 10 seconds to 300 seconds. The thickness of the resist film formed is preferably from 10 nm to 1,000 nm, and more preferably from 10 nm to 500 nm.

When the immersion exposure is carried out, irrespective of presence of a water repellent polymer additive such as the high fluorine-content polymer in the radiation-sensitive composition, the formed resist film may have a protective film for the immersion which is not soluble into the immersion liquid on the film in order to prevent a direct contact between the immersion liquid and the resist film. As the protective film for the immersion, a solvent-removable protective film that is removed with a solvent before the developing step (for example, see JP-A-2006-227632); or a developer-removable protective film that is removed during the development of the developing step (for example, see WO2005-069076 and WO2006-035790) may be used. In terms of the throughput, the developer-removable protective film is preferably used.

When the next step, the exposure step, is performed with radiation having a wavelength of 50 nm or less, it is preferable to use a polymer having the structural unit (I) and the structural unit (IV) as the base polymer in the composition.

### [Exposing Step]

In this step (the above mentioned step (2)), the resist film formed in the resist film forming step as the step (1) is exposed by irradiating with a radioactive ray through a photomask (optionally through an immersion medium such as water). Examples of the radioactive ray used for the exposure include visible ray, ultraviolet ray, far ultraviolet ray, extreme ultraviolet ray (EUV); an electromagnetic wave including X ray and γ ray; an electron beam; and a charged particle radiation such as α ray. Among them, far ultraviolet ray, an electron beam, or EUV is preferred. ArF excimer laser light (wavelength is 193 nm), KrF excimer laser light (wavelength is 248 nm), an electron beam, or EUV is more preferred. ArF excimer laser light or EUV is further preferred.

When the exposure is carried out by immersion exposure, examples of the immersion liquid include water and fluorine-based inert liquid. The immersion liquid is preferably a liquid which is transparent with respect to the exposing wavelength, and has a minimum temperature factor of the refractive index so that the distortion of the light image reflected on the film becomes minimum. However, when the exposing light source is ArF excimer laser light (wavelength is 193 nm), water is preferably used because of the ease of availability and ease of handling in addition to the above considerations. When water is used, a small proportion of an additive that decreases the surface tension of water and increases the surface activity may be added. Preferably, the additive cannot dissolve the resist film on the wafer and can neglect an influence on an optical coating at an under surface of a lens. The water used is preferably distilled water.

After the exposure, post exposure bake (PEB) is preferably carried out to promote the dissociation of the acid-dissociable group in the polymer by the acid generated from the radiation-sensitive acid generator with the exposure in the exposed part of the resist film. The difference of solubility into the developer between the exposed part and the non-exposed part is generated by the PEB. The temperature of PEB is typically from 50° C. to 180° C., and preferably from 80° C. to 130° C. The duration of PEB is typically from 5 seconds to 600 seconds, and preferably from 10 seconds to 300 seconds.

### [Developing Step]

In this step (the above mentioned step (3)), the resist film exposed in the exposing step as the step (2) is developed with a developer. By this step, the predetermined resist pattern can be formed. After the development, the resist pattern is washed with a rinse solution such as water or alcohol, and the dried, in general.

Examples of the developer used for the development include, in the alkaline development, an alkaline aqueous solution obtained by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, 1,5-diazabicyclo-[4.3.0]-5-nonene. Among them, an aqueous TMAH solution is preferred, and 2.38% by mass of aqueous TMAH solution is more preferred.

In the case of the development with organic solvent, examples of the solvent include an organic solvent, including a hydrocarbon-based solvent, an ether-based solvent, an ester-based solvent, a ketone-based solvent, and an alcohol-based solvent; and a solvent containing an organic solvent. Examples of the organic solvent include one, two or more solvents listed as the solvent for the radiation-sensitive composition. Among them, an ether-based solvent, an ester-based solvent or a ketone-based solvent is preferred. As the ether-based solvent, a glycol ether-based solvent is preferable, and ethylene glycol monomethyl ether and propylene glycol monomethyl ether are more preferable. The ester-based solvent is preferably an acetate ester-based solvent, and more preferably n-butyl acetate or amyl acetate. The ketone-based solvent is preferably a chain ketone, and more preferably 2-heptanone. The content of the organic solvent in the developer is preferably not less than 80% by mass, more preferably not less than 90% by mass, further preferably not less than 95% by mass, and particularly preferably not less than 99% by mass. Examples of the ingredient other than the organic solvent in the developer include water and silicone oil.

As described above, the developer may be either an alkaline developer or an organic solvent developer.

Examples of the developing method include a method of dipping the substrate in a tank filled with the developer for a given time (dip method); a method of developing by putting and leaving the developer on the surface of the substrate with the surface tension for a given time (paddle method); a method of spraying the developer on the surface of the substrate (spray method); and a method of injecting the developer while scanning an injection nozzle for the developer at a constant rate on the substrate rolling at a constant rate (dynamic dispense method).

### <Onium Salt (1)>

The onium salt according to still another embodiment of the present invention is represented by the following formula (1).

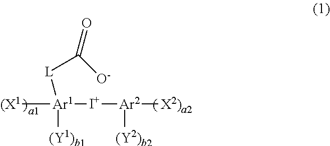

(In the formula (1),
L is a single bond or a divalent linking group having 1 to 5 carbon atoms.
Ar¹ is an (a1+b1+1)-valent aromatic ring.
Ar² is an (a2+b2+1)-valent aromatic ring.
X¹ and X² are each independently a monovalent organic group having 1 to 20 carbon atoms.
Y¹ is a monovalent organic group having 4 to 20 carbon atoms bonded to Ar¹ through —O—, —S—, or —SO₂—, or a monovalent perfluoroalkyl group having 1 to 20 carbon atoms.
Y² is a monovalent organic group having 4 to 20 carbon atoms bonded to Ar² through —O—, —S—, or —SO₂—, or a monovalent perfluoroalkyl group having 1 to 20 carbon atoms.
a1, a2, b1, and b2 are each independently an integer of 0 to 5. However, when the aromatic ring of Ar² is a benzene ring, b1+b2≥1.)

As the onium salt represented by the formula (1) according to the present embodiment, the onium salt (1) contained in the radiation-sensitive composition can be suitably used.

### EXAMPLES

Hereinafter, the present invention will be specifically described with reference to Examples, but the present invention is not limited to these Examples. Methods for measuring various physical property values are shown below.

### [Weight Average Molecular Weight (Mw) and Number Average Molecular Weight (Mn)]

The Mw and Mn of the polymer were measured under the conditions described above. The polydispersity (Mw/Mn) was calculated from the measurement results of Mw and Mn.

### [¹³C-NMR Analysis]

¹³C-NMR analysis of the polymer was performed using a nuclear magnetic resonance apparatus (“JNM-Delta 400” manufactured by JEOL Ltd.).

### <Synthesis of Polymer and High Fluorine-Content Polymer>

The monomers used in the synthesis of each polymer in Examples and Comparative Examples are shown below. In the following synthesis examples, unless otherwise specified, parts by mass means a value when the total mass of monomers used is 100 parts by mass, and mols means a value when the total number of moles of monomers used is 100 mol %.

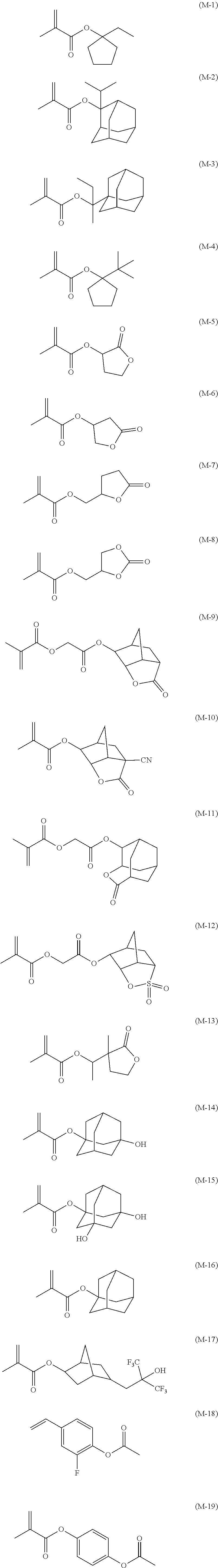

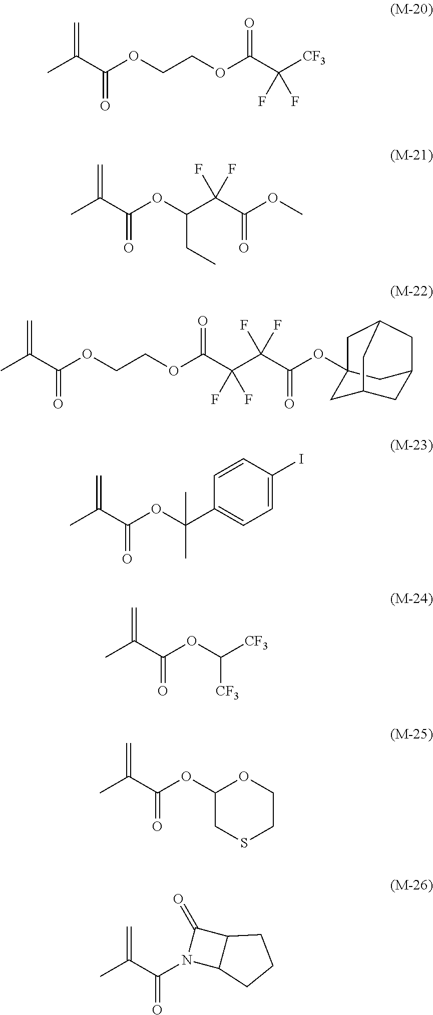

### Synthesis Example 1

### (Synthesis of Polymer (A-1))

A monomer (M-1), a monomer (M-2), a monomer (M-5), a monomer (M-11), and a monomer (M-14) were dissolved at a molar ratio of 40/10/20/20/10 (mol) in 2-butanone (200 parts by mass), and AIBN (azobisisobutyronitrile) (5 mol based on 100 mol % in total of the monomers used) was added thereto as an initiator to prepare a monomer solution. A reaction vessel was charged with 2-butanone (100 parts by mass) and purged with nitrogen for 30 minutes, and inside of the reaction vessel was adjusted to 80° C. Then, the monomer solution was added dropwise thereto over 3 hours with stirring. The polymerization reaction was performed for 6 hours with the start of dropwise addition as the initiation time of the polymerization reaction. After completion of the polymerization reaction, the polymerization solution was cooled to 30° C. or lower by water cooling. The cooled polymerization solution was added to methanol (2,000 parts by mass), and the precipitated white powder was separated by filtration. The separated white powder was washed with methanol twice, then separated by filtration, and dried at 50° C. for 24 hours to obtain a white powdery polymer (A-1) (yield: 80%). The polymer (A-1) had a Mw of 7,100 and a Mw/Mn of 1.61. As a result of ¹³C-NMR analysis, the content ratios of the structural units derived from (M-1), (M-2), (M-5), (M-11), and (M-14) were 40.1 mol %, 9.0 mol %, 20.9 mol %, 24.8 mol %, and 5.2 mol %, respectively.

### Synthesis Examples 2 to 11 and 21 to 22

### (Synthesis of Polymers (A-2) to (A-11) and (A-21) to (A-22))

Polymers (A-2) to (A-11) and (A-21) to (A-22) were synthesized in the same manner as in Synthesis Example 1 except that monomers of types and blending ratios shown in the following Table 1 were used. The content (mol %), yield (%), and physical property values (Mw and Mw/Mn) of each structural unit of the obtained polymers are shown together in the following Table 1. Incidentally, “-” in the following Table 1 indicates that the corresponding monomer was not used (the same applies to the following tables.).

TABLE 1

| | | MONOMER THAT AFFORDS | | | MONOMER THAT AFFORDS | | |
|---|---|---|---|---|---|---|---|
| | | STRUCTURAL UNIT (I) | | | STRUCTURAL UNIT (II) | | |
| | | | | CONTENT | | | CONTENT |
| | | | BLENDING | RATIO OF | | BLENDING | RATIO OF |
| | [A] | | RATIO | STRUCTURAL | | RATIO | STRUCTURAL |
| | POLYMER | TYPE | (mol %) | UNIT (mol %) | TYPE | (mol %) | UNIT (mol %) |
| SYNTHESIS | A-1 | M-1 | 40 | 40.1 | M-5 | 20 | 20.9 |
| EXAMPLE 1 | | M-2 | 10 | 9.0 | M-11 | 25 | 24.8 |
| SYNTHESIS | A-2 | M-1 | 30 | 30.2 | M-9 | 50 | 50.6 |
| EXAMPLE 2 | | M-2 | 20 | 19.2 | | | |
| SYNTHESIS | A-3 | M-1 | 30 | 31.0 | M-10 | 50 | 49.4 |
| EXAMPLE 3 | | M-3 | 20 | 19.6 | | | |
| SYNTHESIS | A-4 | M-4 | 40 | 40.5 | M-8 | 10 | 10.3 |
| EXAMPLE 4 | | M-3 | 20 | 18.9 | M-12 | 20 | 20.1 |
| SYNTHESIS | A-5 | M-4 | 40 | 40.6 | M-10 | 30 | 29.8 |
| EXAMPLE 5 | | M-2 | 10 | 8.1 | M-13 | 20 | 21.5 |
| SYNTHESIS | A-6 | M-1 | 40 | 40.9 | M-6 | 20 | 20.5 |
| EXAMPLE 6 | | M-4 | 10 | 8.3 | M-9 | 20 | 20.3 |
| SYNTHESIS | A-7 | M-4 | 40 | 40.9 | M-5 | 20 | 20.0 |
| EXAMPLE 7 | | M-3 | 10 | 8.3 | M-10 | 20 | 20.5 |
| SYNTHESIS | A-8 | M-4 | 40 | 40.0 | M-7 | 20 | 20.5 |
| EXAMPLE 8 | | M-2 | 10 | 10.1 | M-11 | 20 | 20.2 |
| SYNTHESIS | A-9 | M-1 | 30 | 30.4 | M-8 | 30 | 31.1 |
| EXAMPLE 9 | | | | | M-9 | 40 | 38.5 |
| SYNTHESIS | A-10 | M-2 | 40 | 40.2 | M-12 | 60 | 59.8 |
| EXAMPLE 10 | | | | | | | |
| SYNTHESIS | A-11 | M-4 | 40 | 39.4 | M-5 | 60 | 60.6 |
| EXAMPLE 11 | | | | | | | |
| SYNTHESIS | A-21 | M-25 | 20 | 20.3 | M-5 | 20 | 20.8 |
| EXAMPLE 21 | | M-2 | 40 | 38.4 | M-9 | 15 | 15.7 |
| SYNTHESIS | A-22 | M-3 | 10 | 9.3 | M-11 | 25 | 25.4 |
| EXAMPLE 21 | | M-4 | 40 | 39.5 | M-26 | 20 | 20.3 |

| | MONOMER THAT AFFORDS | | | | |
|---|---|---|---|---|---|
| | STRUCTURAL UNIT (III) OR (VII) | | | | |
| | | | CONTENT | | |
| | | BLENDING | RATIO OF | | |
| | | RATIO | STRUCTURAL | | |
| | TYPE | (mol %) | UNIT (mol %) | Mw | Mw/Mn |
| SYNTHESIS | M-14 | 5 | 5.2 | 7100 | 1.61 |
| EXAMPLE 1 | | | | | |
| SYNTHESIS | — | — | — | 7700 | 1.51 |
| EXAMPLE 2 | | | | | |
| SYNTHESIS | — | — | — | 7200 | 1.59 |
| EXAMPLE 3 | | | | | |
| SYNTHESIS | M-15 | 10 | 10.2 | 6800 | 1.61 |
| EXAMPLE 4 | | | | | |
| SYNTHESIS | — | — | — | 6900 | 1.44 |
| EXAMPLE 5 | | | | | |
| SYNTHESIS | M-16 | 10 | 10.0 | 7500 | 1.51 |
| EXAMPLE 6 | | | | | |
| SYNTHESIS | M-14 | 10 | 10.3 | 7200 | 1.55 |
| EXAMPLE 7 | | | | | |
| SYNTHESIS | M-15 | 10 | 9.2 | 7100 | 1.62 |
| EXAMPLE 8 | | | | | |
| SYNTHESIS | — | — | — | 7000 | 1.51 |
| EXAMPLE 9 | | | | | |
| SYNTHESIS | — | — | — | 10300 | 1.66 |
| EXAMPLE 10 | | | | | |
| SYNTHESIS | — | — | — | 13200 | 1.67 |
| EXAMPLE 11 | | | | | |
| SYNTHESIS | M-15 | 5 | 4.8 | 7600 | 1.60 |
| EXAMPLE 21 | | | | | |
| SYNTHESIS | M-14 | 5 | 5.5 | 4300 | 1.55 |
| EXAMPLE 21 | | | | | |

### Synthesis Example 12

### (Synthesis of Polymer (A-12))

The monomer (M-1), (M-15) and the monomer (M-18) were dissolved in 1-methoxy-2-propanol (200 parts by mass) so as to have a molar ratio of 40/10/50 (mol %), and AIBN (5 mol %) was added as an initiator to prepare a monomer solution. A reaction vessel was charged with 1-methoxy-2-propanol (100 parts by mass) and purged with nitrogen for 30 minutes, and inside of the reaction vessel was adjusted to 80° C. Then, the monomer solution was added dropwise thereto over 3 hours with stirring. The polymerization reaction was performed for 6 hours with the start of dropwise addition as the initiation time of the polymerization reaction. After completion of the polymerization reaction, the polymerization solution was cooled to 30° C. or lower by water cooling. The cooled polymerization solution was added to hexane (2,000 parts by mass), and the precipitated white powder was separated by filtration. The separated white powder was washed twice with hexane, then separated by filtration, and dissolved in 1-methoxy-2-propanol (300 parts by mass). Subsequently, methanol (500 parts by mass), triethylamine (50 parts by mass), and ultrapure water (10 parts by mass) were added, and a hydrolysis reaction was performed at 70° C. for 6 hours with stirring. After completion of the reaction, the remaining solvent was distilled off, and the obtained solid was dissolved in acetone (100 parts by mass). The solution was added dropwise to water (500 parts by mass) to solidify the polymer. The resulting solid was separated by filtration and dried at 50° C. for 13 hours to obtain a white powdery polymer (A-12) (yield: 81%). The polymer (A-12) had a Mw of 5, 700 and a Mw/Mn of 1.66. As a result of ¹³C-NMR analysis, the content ratios of the structural units derived from (M-1), (M-15), and (M-18) were 39.8 mol %, 10.1 mol %, and 50.1 mol %, respectively.

### Synthesis Examples 13 to 15

### (Synthesis of Polymers (A-13) to (A-15))

Polymers (A-13) to (A-15) were synthesized in the same manner as in Synthesis Example 12 except that monomers of types and blending ratios shown in the following Table 2 were used. For the monomer that affords the structural unit (IV), in the polymer, the disappearance of the peak of the carbonyl group on the acetyl group was confirmed by measurement of ¹³C-NMR, and substantially all the alkali-dissociable groups were hydrolyzed to phenolic hydroxyl groups. The content (mol %), and physical property values (Mw and Mw/Mn) of each structural unit of the obtained polymers are also shown in the following Table 2.

TABLE 2

| | | MONOMER THAT AFFORDS | | | MONOMER THAT AFFORDS | | |
|---|---|---|---|---|---|---|---|
| | | STRUCTURAL UNIT (I) | | | STRUCTURAL UNIT (III) | | |
| | | | | CONTENT | | | CONTENT |
| | | | BLENDING | RATIO OF | | BLENDING | RATIO OF |
| | [A] | | RATIO | STRUCTURAL | | RATIO | STRUCTURAL |
| | POLYMER | TYPE | (mol %) | UNIT (mol %) | TYPE | (mol %) | UNIT (mol %) |
| SYNTHESIS | A-12 | M-1 | 40 | 39.8 | M-15 | 10 | 10.1 |
| EXAMPLE 12 | | | | | | | |
| SYNTHESIS | A-13 | M-23 | 50 | 46.6 | M-17 | 10 | 11.1 |
| EXAMPLE 13 | | | | | | | |
| SYNTHESIS | A-14 | M-2 | 50 | 48.1 | M-14 | 20 | 21.3 |
| EXAMPLE 14 | | | | | | | |
| SYNTHESIS | A-15 | M-4 | 55 | 53.2 | M-17 | 15 | 15.2 |
| EXAMPLE 15 | | | | | | | |

| | MONOMER THAT AFFORDS | | | | |
|---|---|---|---|---|---|
| | STRUCTURAL UNIT (IV) | | | | |
| | | | CONTENT | | |
| | | BLENDING | RATIO OF | | |
| | | RATIO | STRUCTURAL | | |
| | TYPE | (mol %) | UNIT (mol %) | Mw | Mw/Mn |
| SYNTHESIS | M-18 | 50 | 50.1 | 5700 | 1.66 |
| EXAMPLE 12 | | | | | |
| SYNTHESIS | M-19 | 40 | 42.3 | 5600 | 1.55 |
| EXAMPLE 13 | | | | | |
| SYNTHESIS | M-18 | 30 | 30.6 | 5100 | 1.59 |
| EXAMPLE 14 | | | | | |
| SYNTHESIS | M-19 | 30 | 31.6 | 6100 | 1.50 |
| EXAMPLE 15 | | | | | |

### Synthesis Example 16

### (Synthesis of High Fluorine-Content Polymer (F-1))

A monomer (M-2), a monomer (M-4), a monomer (M-15), a monomer (M-16), a monomer (M-20), and a monomer (M-22) were dissolved at a molar ratio of 10/20/5/5/40/20 (mol %) in 2-butanone (200 parts by mass), followed by addition of AIBN (3 mol %) as an initiator to prepare a monomer solution. A reaction vessel was charged with 2-butanone (100 parts by mass) and purged with nitrogen for 30 minutes, and inside of the reaction vessel was adjusted to 80° C. Then, the monomer solution was added dropwise thereto over 3 hours with stirring. The polymerization reaction was performed for 6 hours with the start of dropwise addition as the initiation time of the polymerization reaction. After completion of the polymerization reaction, the polymerization solution was cooled to 30° C. or lower by water cooling. The operation of replacing the solvent with acetonitrile (400 parts by mass), then adding hexane (100 parts by mass), stirring the mixture, and recovering the acetonitrile layer was repeated three times. The solvent was replaced with propylene glycol monomethyl ether acetate to obtain a solution of a high fluorine-content polymer (F-1) (yield: 75%). The high fluorine-content polymer (F-1) had a Mw of 9,800 and a Mw/Mn of 1.71. As a result of ¹³C-NMR analysis, the content ratios of the structural units derived from (M-2), (M-4), (M-15), (M-16), (M-20), and (M-22) were 8.7 mol %, 19.3 mol %, 5.4 mol %, 6.1 mol %, 40.9 mol %, and 19.6 mol %, respectively.

### Synthesis Examples 17 to 20

### (Synthesis of High Fluorine-Content Polymers (F-2) to (F-5))

High fluorine-content polymers (F-2) to (F-5) were synthesized in the same manner as in Synthesis Example 16 except that monomers of the types and blending ratios shown in the following Table 3 were used. The content (mol %), and physical property values (Mw and Mw/Mn) of each structural unit of the obtained high fluorine-content polymers are shown in the following Table 3.

TABLE 3

| | | MONOMER THAT | | | MONOMER THAT | | |
|---|---|---|---|---|---|---|---|
| | | AFFORDS STRUCTURAL | | | AFFORDS STRUCTURAL | | |
| | | UNIT (V) OR (VI) | | | UNIT (I) | | |
| | | | | RATIO OF | | | CONTENT |
| | [F] HIGH | | | CONTENT | | | RATIO OF |
| | FLUORINE- | | BLENDING | STRUCTURAL | | BLENDING | STRUCTURAL |
| | CONTENT | | RATIO | UNIT | | RATIO | UNIT |
| | POLYMER | TYPE | (mol %) | (mol %) | TYPE | (mol %) | (mol %) |
| SYNTHESIS | F-1 | M-20 | 40 | 40.9 | M-2 | 10 | 8.7 |
| EXAMPLE 16 | | M-22 | 20 | 19.6 | M-4 | 20 | 19.3 |
| SYNTHESIS | F-2 | M-21 | 60 | 60.6 | M-1 | 20 | 20.3 |
| EXAMPLE 17 | | M-24 | 10 | 10.2 | M-3 | 10 | 8.9 |
| SYNTHESIS | F-3 | M-22 | 60 | 62.3 | — | — | — |
| EXAMPLE 18 | | | | | | | |
| SYNTHESIS | F-4 | M-22 | 60 | 60.2 | M-2 | 20 | 19.4 |
| EXAMPLE 19 | | | | | | | |
| SYNTHESIS | F-5 | M-22 | 60 | 60.0 | M-23 | 10 | 10.1 |
| EXAMPLE 20 | | | | | | | |

| | MONOMER THAT | | | MONOMER THAT | | | | |
|---|---|---|---|---|---|---|---|---|
| | AFFORDS STRUCTURAL | | | AFFORDS STRUCTURAL | | | | |
| | UNIT (III) | | | UNIT (VII) | | | | |
| | | | RATIO OF | | | CONTENT | | |
| | | | CONTENT | | | RATIO OF | | |
| | | BLENDING | STRUCTURAL | | BLENDING | STRUCTURAL | | |
| | | RATIO | UNIT | | RATIO | UNIT | | Mw/ |
| | TYPE | (mol %) | (mol %) | TYPE | (mol %) | (mol %) | Mw | Mn |
| SYNTHESIS | M-15 | 5 | 5.4 | M-16 | 5 | 6.1 | 9800 | 1.71 |
| EXAMPLE 16 | | | | | | | | |
| SYNTHESIS | — | — | — | — | — | — | 9100 | 1.78 |
| EXAMPLE 17 | | | | | | | | |
| SYNTHESIS | — | — | — | M-16 | 40 | 37.7 | 9000 | 1.98 |
| EXAMPLE 18 | | | | | | | | |
| SYNTHESIS | M-14 | 20 | 20.4 | — | — | — | 9500 | 1.89 |
| EXAMPLE 19 | | | | | | | | |
| SYNTHESIS | M-17 | 30 | 29.9 | — | — | — | 8700 | 1.76 |
| EXAMPLE 20 | | | | | | | | |

### <Synthesis of [C] Onium Salt (1)>

### Example C1

### (Synthesis of Onium Salt (C-1))

A [C] onium salt (C-1) as an acid diffusion controlling agent was synthesized according to the following synthesis scheme.

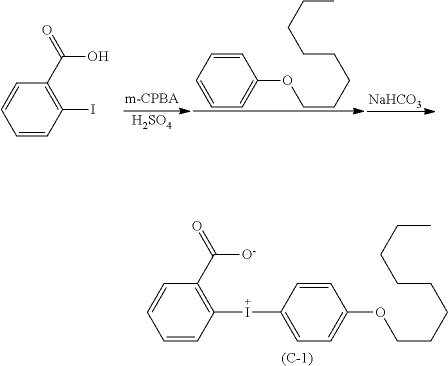

To a reaction vessel were added 20.0 mmol of 2-iodobenzoic acid, 20.0 mmol of meta-chloroperbenzoic acid (m-CPBA), 25.0 mmol of sulfuric acid, and 50 g of dichloromethane, followed by stirring for 1 hour under ice cooling. Thereafter, 30.0 mmol of n-octyloxybenzene was added, followed by further stirring for 3 hours. Then, 100 g of a saturated aqueous sodium bicarbonate solution was added, followed by further stirring at room temperature for 24 hours. To the obtained reaction solution, methylene chloride was added for extraction, and then the organic layer was separated. After the obtained organic layer was dried over sodium sulfate, the solvent was distilled off, and the residue was purified by recrystallization, affording an onium salt (C-1) represented by the formula (C-1) in a good yield.

### Examples C2 to C37

### (Synthesis of Onium Salts (C-2) to (C-37))

Salt compounds as acid diffusion controlling agents represented by the following formulas (C-2) to (C-37) were synthesized in the same manner as in Example C1 except that the raw materials and the precursor were appropriately changed.

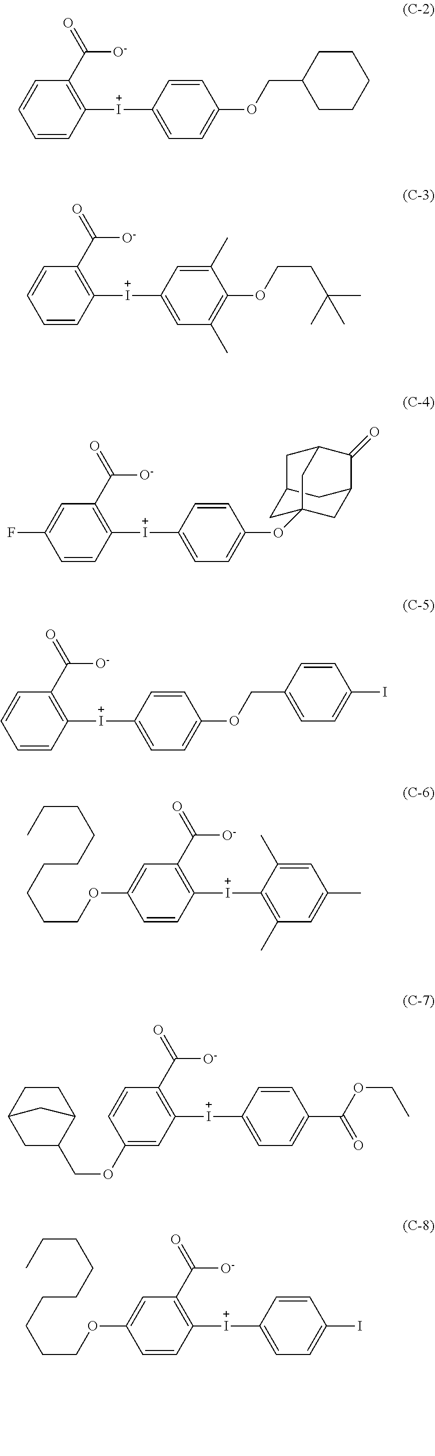

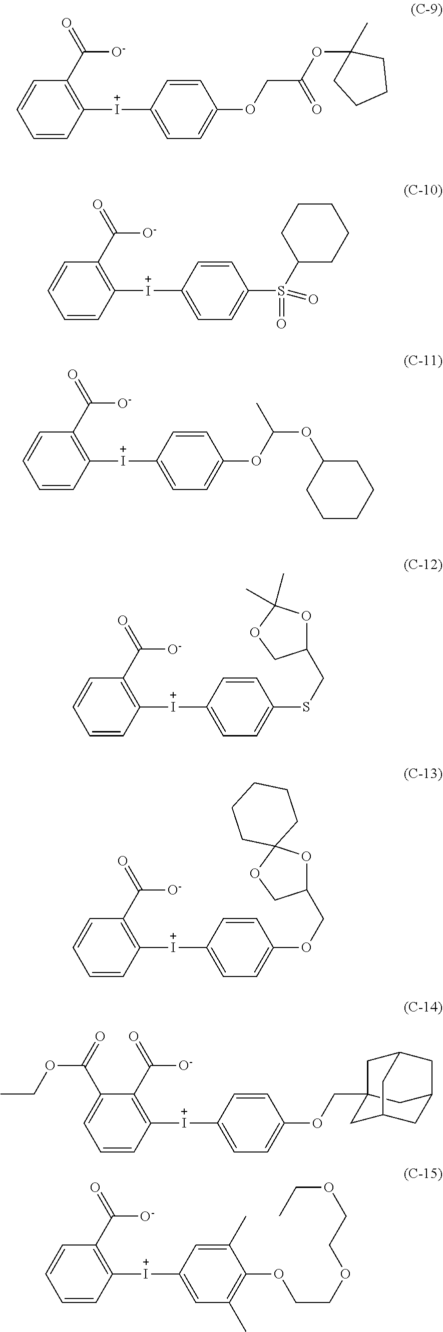

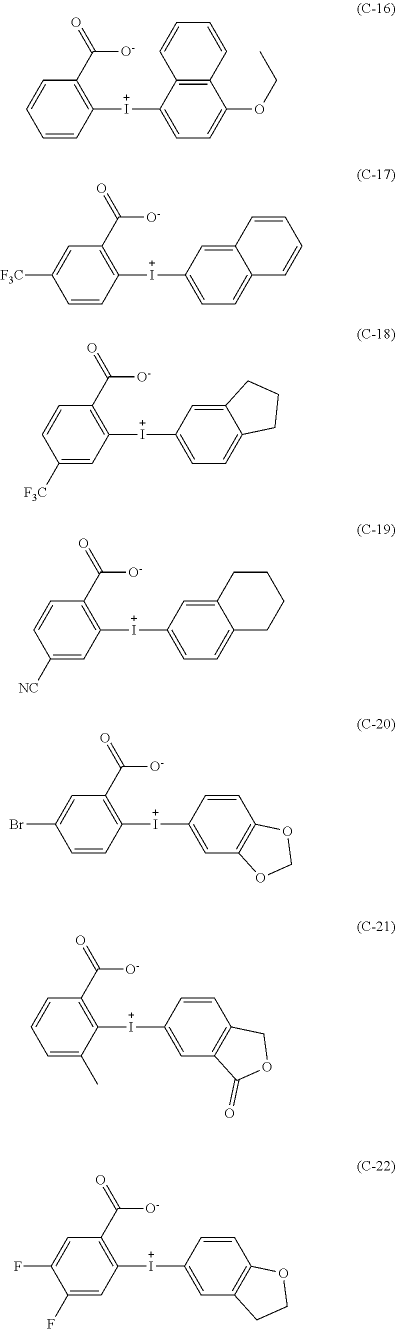

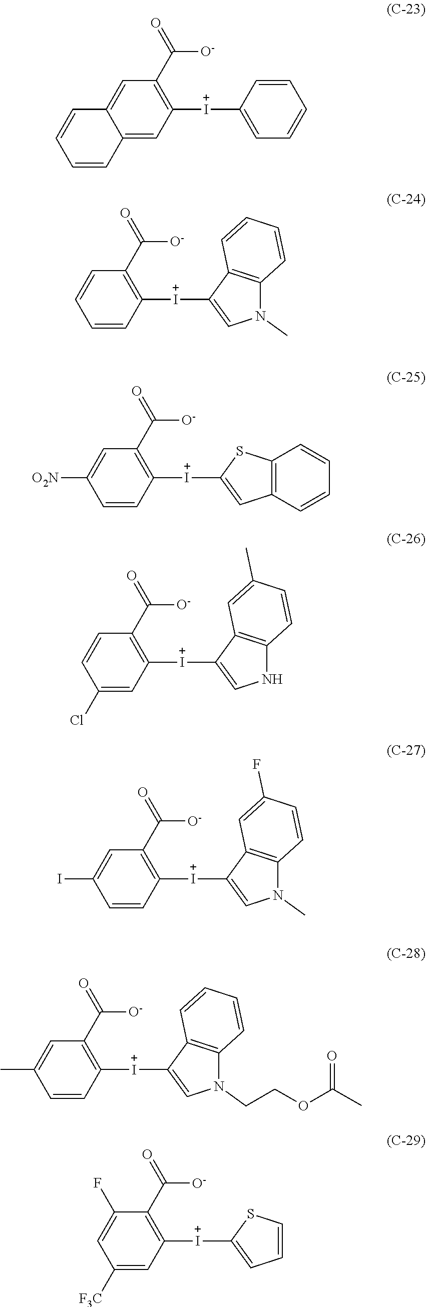

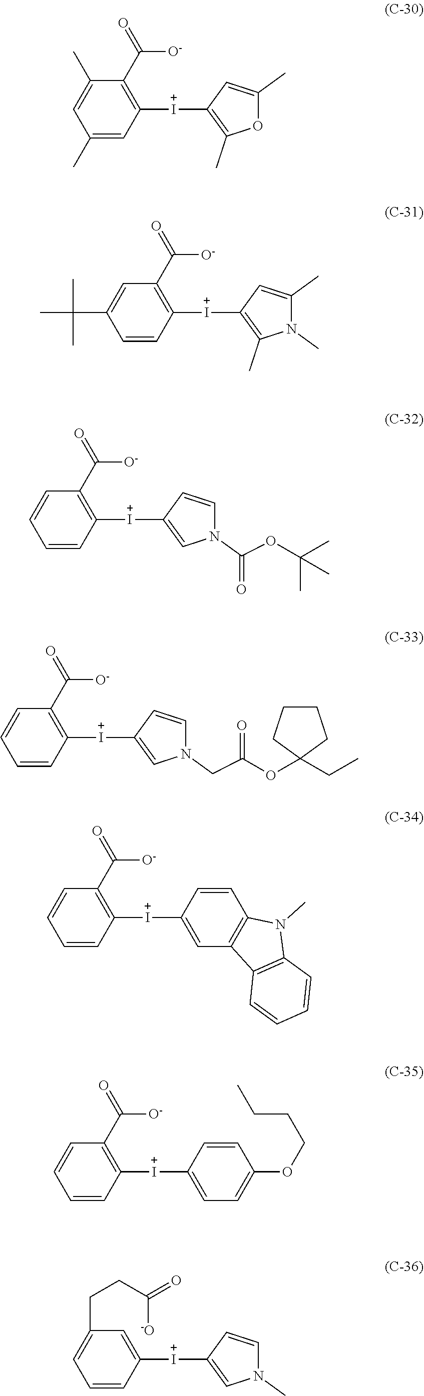

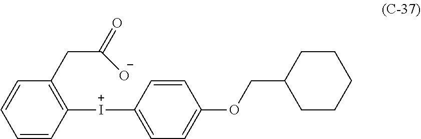 [SMILES: O=C([O-])Cc1ccccc1[I+]c1ccc(OCC2CCCCC2)cc1]

The following compounds were used as components other than the synthesized components.

[Acid Diffusion Controlling Agent Other than Onium Salts (C-1) to (C-37)]

cc-1 to cc-7: Compounds represented by the following formulas (cc-1) to (cc-7) (hereinafter, the compounds represented by the formulas (cc-1) to (cc-7) may be described as “compound (cc-1)” to “compound (cc-7)”, respectively).

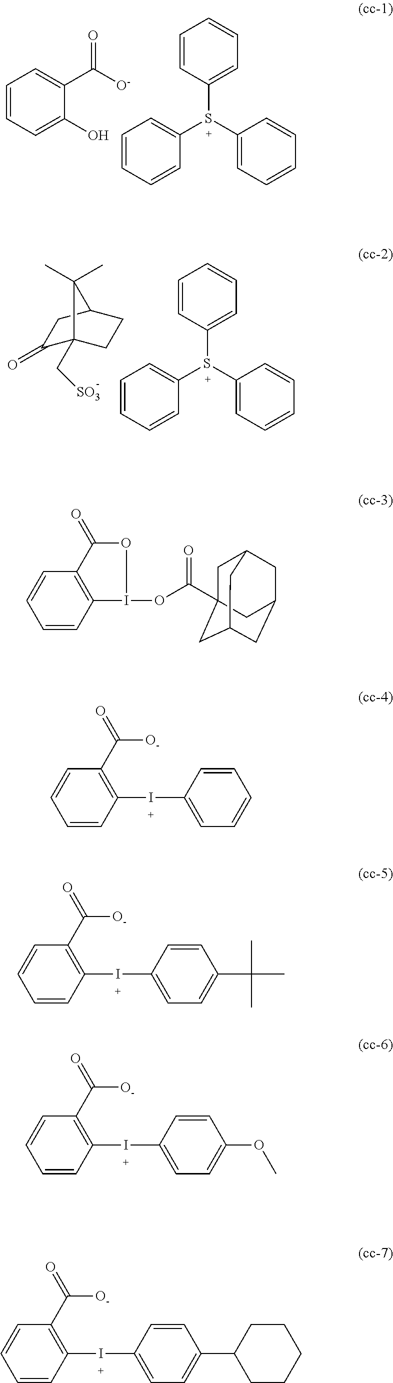

### [[B] Radiation-Sensitive Acid Generator]

B-1 to B-7: Compounds represented by the following formulas (B-1) to (B-9).

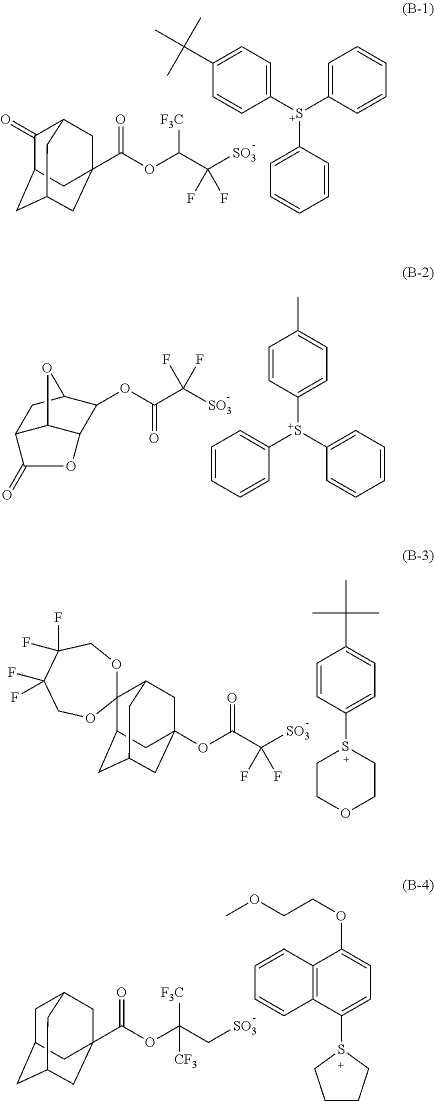

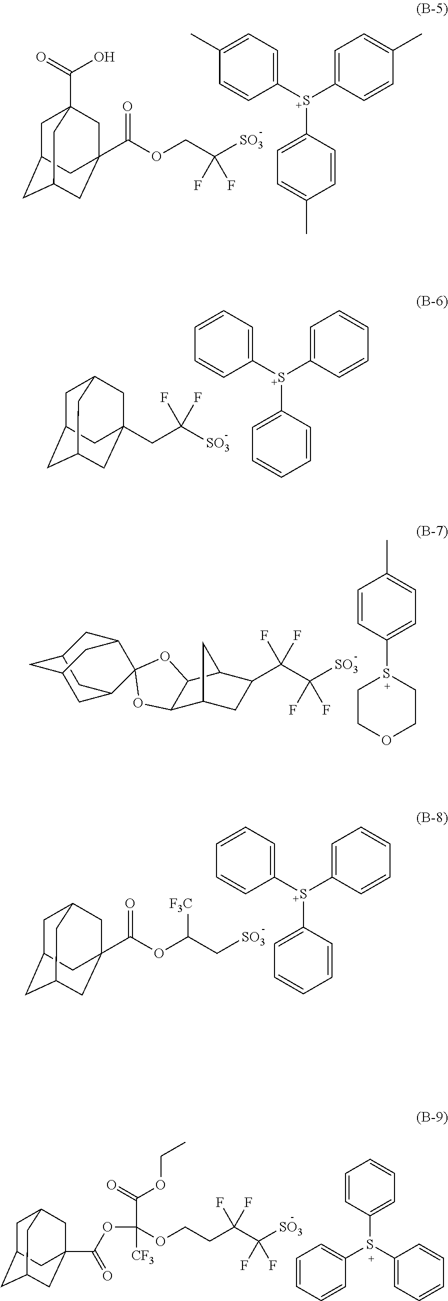

### [[E] Solvent]

E-1: Propylene glycol monomethyl ether acetate
E-2: Propylene glycol monomethyl ether
E-3: γ-Butyrolactone
E-4: Ethyl lactate

### [Preparation of Negative Radiation-Sensitive Composition for ArF Exposure]

### Example 1

Mixed were 100 parts by mass of (A-1) as an [A] polymer, 8.0 parts by mass of (B-1) as a [B] radiation-sensitive acid generator, 6.0 parts by mass of (C-1) as a [C] onium salt (1), 5.0 parts by mass (solid content) of (F-1) as an [F] high fluorine-content polymer, and 3,400 parts by mass (2,000/1,200/200 parts by mass) of a mixed solvent of (E-1)/(E-2)/(E-3) as an [E] solvent, followed by filtration through a membrane filter having a pore size of 0.2 μm to prepare a radiation-sensitive composition (J-1).

### Examples 2 to 67 and 96 to 97, and Comparative Examples 1 to 7

Radiation-sensitive compositions (J-2) to (J-67), (J-96) to (J-97), and (CJ-1) to (CJ-7) were prepared in the same manner as in Example 1 except that the respective components of the types and contents shown in the following Table 4 were used.

TABLE 4

| | | | | [B] RADIATION- | | | |
|---|---|---|---|---|---|---|---|
| | | | | SENSITIVE ACID | | | |
| | | [A] POLYMER | | GENERATOR | | [C] ONIUM SALT (1) | |
| | | | CONTENT | | CONTENT | | CONTENT |
| | RADIATION- | | (PARTS | | (PARTS | | (PARTS |
| | SENSITIVE | | BY | | BY | | BY |
| | COMPOSITION | TYPE | MASS) | TYPE | MASS) | TYPE | MASS) |
| EXAMPLE 1 | J-1 | A-1 | 100 | B-1 | 8.0 | C-1 | 6.0 |
| EXAMPLE 2 | J-2 | A-2 | 100 | B-1 | 8.0 | C-1 | 6.0 |
| EXAMPLE 3 | J-3 | A-3 | 100 | B-1 | 8.0 | C-1 | 6.0 |
| EXAMPLE 4 | J-4 | A-4 | 100 | B-1 | 8.0 | C-1 | 6.0 |
| EXAMPLE 5 | J-5 | A-5 | 100 | B-1 | 8.0 | C-1 | 6.0 |
| EXAMPLE 6 | J-6 | A-6 | 100 | B-1 | 8.0 | C-1 | 6.0 |
| EXAMPLE 7 | J-7 | A-7 | 100 | B-1 | 8.0 | C-1 | 6.0 |
| EXAMPLE 8 | J-8 | A-8 | 100 | B-1 | 8.0 | C-1 | 6.0 |
| EXAMPLE 9 | J-9 | A-9 | 100 | B-1 | 8.0 | C-1 | 6.0 |
| EXAMPLE 10 | J-10 | A-10 | 100 | B-1 | 8.0 | C-1 | 6.0 |
| EXAMPLE 11 | J-11 | A-11 | 100 | B-1 | 8.0 | C-1 | 6.0 |
| EXAMPLE 96 | J-96 | A-21 | 100 | B-1 | 8.0 | C-1 | 6.0 |
| EXAMPLE 97 | J-97 | A-22 | 100 | B-1 | 8.0 | C-1 | 6.0 |
| EXAMPLE 12 | J-12 | A-1 | 100 | B-1 | 8.0 | C-2 | 6.0 |
| EXAMPLE 13 | J-13 | A-1 | 100 | B-1 | 8.0 | C-3 | 6.0 |
| EXAMPLE 14 | J-14 | A-1 | 100 | B-1 | 8.0 | C-4 | 6.0 |
| EXAMPLE 15 | J-15 | A-1 | 100 | B-1 | 8.0 | C-5 | 6.0 |
| EXAMPLE 16 | J-16 | A-1 | 100 | B-1 | 8.0 | C-6 | 6.0 |
| EXAMPLE 17 | J-17 | A-1 | 100 | B-1 | 8.0 | C-7 | 6.0 |
| EXAMPLE 18 | J-18 | A-1 | 100 | B-1 | 8.0 | C-8 | 6.0 |
| EXAMPLE 19 | J-19 | A-1 | 100 | B-1 | 8.0 | C-9 | 6.0 |
| EXAMPLE 20 | J-20 | A-1 | 100 | B-1 | 8.0 | C-10 | 6.0 |
| EXAMPLE 21 | J-21 | A-1 | 100 | B-1 | 8.0 | C-11 | 6.0 |
| EXAMPLE 22 | J-22 | A-1 | 100 | B-1 | 8.0 | C-12 | 6.0 |
| EXAMPLE 23 | J-23 | A-1 | 100 | B-1 | 8.0 | C-13 | 6.0 |
| EXAMPLE 24 | J-24 | A-1 | 100 | B-1 | 8.0 | C-14 | 6.0 |
| EXAMPLE 25 | J-25 | A-1 | 100 | B-1 | 8.0 | C-15 | 6.0 |
| EXAMPLE 26 | J-26 | A-1 | 100 | B-1 | 8.0 | C-16 | 6.0 |
| EXAMPLE 27 | J-27 | A-1 | 100 | B-1 | 8.0 | C-17 | 6.0 |
| EXAMPLE 28 | J-28 | A-1 | 100 | B-1 | 8.0 | C-18 | 6.0 |
| EXAMPLE 29 | J-29 | A-1 | 100 | B-1 | 8.0 | C-19 | 6.0 |
| EXAMPLE 30 | J-30 | A-1 | 100 | B-1 | 8.0 | C-20 | 6.0 |
| EXAMPLE 31 | J-31 | A-1 | 100 | B-1 | 8.0 | C-21 | 6.0 |
| EXAMPLE 32 | J-32 | A-1 | 100 | B-1 | 8.0 | C-22 | 6.0 |
| EXAMPLE 33 | J-33 | A-1 | 100 | B-1 | 8.0 | C-23 | 6.0 |
| EXAMPLE 34 | J-34 | A-1 | 100 | B-1 | 8.0 | C-24 | 6.0 |
| EXAMPLE 35 | J-35 | A-1 | 100 | B-1 | 8.0 | C-25 | 6.0 |
| EXAMPLE 36 | J-36 | A-1 | 100 | B-1 | 8.0 | C-26 | 6.0 |
| EXAMPLE 37 | J-37 | A-1 | 100 | B-1 | 8.0 | C-27 | 6.0 |
| EXAMPLE 38 | J-38 | A-1 | 100 | B-1 | 8.0 | C-28 | 6.0 |
| EXAMPLE 39 | J-39 | A-1 | 100 | B-1 | 8.0 | C-29 | 6.0 |
| EXAMPLE 40 | J-40 | A-1 | 100 | B-1 | 8.0 | C-30 | 6.0 |
| EXAMPLE 41 | J-41 | A-1 | 100 | B-1 | 8.0 | C-31 | 6.0 |
| EXAMPLE 42 | J-42 | A-1 | 100 | B-1 | 8.0 | C-32 | 6.0 |
| EXAMPLE 43 | J-43 | A-1 | 100 | B-1 | 8.0 | C-33 | 6.0 |
| EXAMPLE 44 | J-44 | A-1 | 100 | B-1 | 8.0 | C-34 | 6.0 |
| EXAMPLE 45 | J-45 | A-1 | 100 | B-1 | 8.0 | C-35 | 6.0 |
| EXAMPLE 46 | J-46 | A-1 | 100 | B-1 | 8.0 | C-36 | 6.0 |
| EXAMPLE 47 | J-47 | A-1 | 100 | B-1 | 8.0 | C-37 | 6.0 |
| EXAMPLE 48 | J-48 | A-1 | 100 | B-1 | 8.0 | C-1/cc-2 | 4.0/2.0 |
| EXAMPLE 49 | J-49 | A-1 | 100 | B-2 | 8.0 | C-1 | 6.0 |
| EXAMPLE 50 | J-50 | A-1 | 100 | B-3 | 8.0 | C-1 | 6.0 |
| EXAMPLE 51 | J-51 | A-1 | 100 | B-4 | 8.0 | C-1 | 6.0 |
| EXAMPLE 52 | J-52 | A-1 | 100 | B-5 | 8.0 | C-1 | 6.0 |
| EXAMPLE 53 | J-53 | A-1 | 100 | B-6 | 8.0 | C-1 | 6.0 |
| EXAMPLE 54 | J-54 | A-1 | 100 | B-7 | 8.0 | C-1 | 6.0 |
| EXAMPLE 55 | J-55 | A-1 | 100 | B-8 | 8.0 | C-1 | 6.0 |
| EXAMPLE 56 | J-56 | A-1 | 100 | B-9 | 8.0 | C-1 | 6.0 |
| EXAMPLE 57 | J-57 | A-1 | 100 | B-1/B-3 | 4.0/4.0 | C-1 | 6.0 |
| EXAMPLE 58 | J-58 | A-1 | 100 | B-4/B-6 | 4.0/4.0 | C-1 | 6.0 |
| EXAMPLE 59 | J-59 | A-1 | 100 | B-7/B-5 | 4.0/4.0 | C-1 | 6.0 |
| EXAMPLE 60 | J-60 | A-1 | 100 | B-8/B-9 | 4.0/4.0 | C-1 | 6.0 |
| EXAMPLE 61 | J-61 | A-1 | 100 | B-3/B-9 | 4.0/4.0 | C-1 | 6.0 |
| EXAMPLE 62 | J-62 | A-1 | 100 | B-3/B-9 | 4.0/4.0 | C-1 | 6.0 |
| EXAMPLE 63 | J-63 | A-1 | 100 | B-1 | 8.0 | C-1 | 2.0 |
| EXAMPLE 64 | J-64 | A-1 | 100 | B-1 | 8.0 | C-1 | 15.0 |
| EXAMPLE 65 | J-65 | A-1 | 100 | B-1 | 8.0 | C-1 | 6.0 |
| EXAMPLE 66 | J-66 | A-1 | 100 | B-1 | 8.0 | C-1 | 6.0 |
| EXAMPLE 67 | J-67 | A-1 | 100 | B-1 | 8.0 | C-1 | 6.0 |
| COMPARATIVE | CJ-1 | A-1 | 100 | B-1 | 8.0 | cc-1 | 6.0 |
| EXAMPLE 1 | | | | | | | |
| COMPARATIVE | CJ-2 | A-1 | 100 | B-1 | 8.0 | cc-2 | 6.0 |
| EXAMPLE 2 | | | | | | | |
| COMPARATIVE | CJ-3 | A-1 | 100 | B-1 | 8.0 | cc-3 | 6.0 |
| EXAMPLE 3 | | | | | | | |
| COMPARATIVE | CJ-4 | A-1 | 100 | B-1 | 8.0 | cc-4 | 6.0 |
| EXAMPLE 4 | | | | | | | |
| COMPARATIVE | CJ-5 | A-1 | 100 | B-1 | 8.0 | cc-5 | 6.0 |
| EXAMPLE 5 | | | | | | | |
| COMPARATIVE | CJ-6 | A-1 | 100 | B-1 | 8.0 | cc-6 | 6.0 |
| EXAMPLE 6 | | | | | | | |
| COMPARATIVE | CJ-7 | A-1 | 100 | B-1 | 8.0 | cc-7 | 6.0 |
| EXAMPLE 7 | | | | | | | |

| | [F] HIGH FLUORINE- | | | |
|---|---|---|---|---|
| | CONTENT POLYMER | | [E] SOLVENT | |
| | | CONTENT | | CONTENT |
| | | (PARTS | | (PARTS |
| | | BY | | BY |
| | TYPE | MASS) | TYPE | MASS) |
| EXAMPLE 1 | F-1 | 5.0 | E-1/E-2/E-3 | 2000/1200/200 |
| EXAMPLE 2 | F-1 | 5.0 | E-1/E-2/E-3 | 2000/1200/200 |
| EXAMPLE 3 | F-1 | 5.0 | E-1/E-2/E-3 | 2000/1200/200 |
| EXAMPLE 4 | F-1 | 5.0 | E-1/E-2/E-3 | 2000/1200/200 |
| EXAMPLE 5 | F-1 | 5.0 | E-1/E-2/E-3 | 2000/1200/200 |
| EXAMPLE 6 | F-1 | 5.0 | E-1/E-2/E-3 | 2000/1200/200 |
| EXAMPLE 7 | F-1 | 5.0 | E-1/E-2/E-3 | 2000/1200/200 |
| EXAMPLE 8 | F-1 | 5.0 | E-1/E-2/E-3 | 2000/1200/200 |
| EXAMPLE 9 | F-1 | 5.0 | E-1/E-2/E-3 | 2000/1200/200 |
| EXAMPLE 10 | F-1 | 5.0 | E-1/E-2/E-3 | 2000/1200/200 |
| EXAMPLE 11 | F-1 | 5.0 | E-1/E-2/E-3 | 2000/1200/200 |
| EXAMPLE 96 | F-1 | 5.0 | E-1/E-2/E-3 | 2000/1200/200 |
| EXAMPLE 97 | F-1 | 5.0 | E-1/E-2/E-3 | 2000/1200/200 |
| EXAMPLE 12 | F-1 | 5.0 | E-1/E-2/E-3 | 2000/1200/200 |
| EXAMPLE 13 | F-1 | 5.0 | E-1/E-2/E-3 | 2000/1200/200 |
| EXAMPLE 14 | F-1 | 5.0 | E-1/E-2/E-3 | 2000/1200/200 |
| EXAMPLE 15 | F-1 | 5.0 | E-1/E-2/E-3 | 2000/1200/200 |
| EXAMPLE 16 | F-1 | 5.0 | E-1/E-2/E-3 | 2000/1200/200 |
| EXAMPLE 17 | F-1 | 5.0 | E-1/E-2/E-3 | 2000/1200/200 |
| EXAMPLE 18 | F-1 | 5.0 | E-1/E-2/E-3 | 2000/1200/200 |
| EXAMPLE 19 | F-1 | 5.0 | E-1/E-2/E-3 | 2000/1200/200 |
| EXAMPLE 20 | F-1 | 5.0 | E-1/E-2/E-3 | 2000/1200/200 |
| EXAMPLE 21 | F-1 | 5.0 | E-1/E-2/E-3 | 2000/1200/200 |
| EXAMPLE 22 | F-1 | 5.0 | E-1/E-2/E-3 | 2000/1200/200 |
| EXAMPLE 23 | F-1 | 5.0 | E-1/E-2/E-3 | 2000/1200/200 |
| EXAMPLE 24 | F-1 | 5.0 | E-1/E-2/E-3 | 2000/1200/200 |
| EXAMPLE 25 | F-1 | 5.0 | E-1/E-2/E-3 | 2000/1200/200 |
| EXAMPLE 26 | F-1 | 5.0 | E-1/E-2/E-3 | 2000/1200/200 |
| EXAMPLE 27 | F-1 | 5.0 | E-1/E-2/E-3 | 2000/1200/200 |
| EXAMPLE 28 | F-1 | 5.0 | E-1/E-2/E-3 | 2000/1200/200 |
| EXAMPLE 29 | F-1 | 5.0 | E-1/E-2/E-3 | 2000/1200/200 |
| EXAMPLE 30 | F-1 | 5.0 | E-1/E-2/E-3 | 2000/1200/200 |
| EXAMPLE 31 | F-1 | 5.0 | E-1/E-2/E-3 | 2000/1200/200 |
| EXAMPLE 32 | F-1 | 5.0 | E-1/E-2/E-3 | 2000/1200/200 |
| EXAMPLE 33 | F-1 | 5.0 | E-1/E-2/E-3 | 2000/1200/200 |
| EXAMPLE 34 | F-1 | 5.0 | E-1/E-2/E-3 | 2000/1200/200 |
| EXAMPLE 35 | F-1 | 5.0 | E-1/E-2/E-3 | 2000/1200/200 |
| EXAMPLE 36 | F-1 | 5.0 | E-1/E-2/E-3 | 2000/1200/200 |
| EXAMPLE 37 | F-1 | 5.0 | E-1/E-2/E-3 | 2000/1200/200 |
| EXAMPLE 38 | F-1 | 5.0 | E-1/E-2/E-3 | 2000/1200/200 |
| EXAMPLE 39 | F-1 | 5.0 | E-1/E-2/E-3 | 2000/1200/200 |
| EXAMPLE 40 | F-1 | 5.0 | E-1/E-2/E-3 | 2000/1200/200 |
| EXAMPLE 41 | F-1 | 5.0 | E-1/E-2/E-3 | 2000/1200/200 |
| EXAMPLE 42 | F-1 | 5.0 | E-1/E-2/E-3 | 2000/1200/200 |
| EXAMPLE 43 | F-1 | 5.0 | E-1/E-2/E-3 | 2000/1200/200 |
| EXAMPLE 44 | F-1 | 5.0 | E-1/E-2/E-3 | 2000/1200/200 |
| EXAMPLE 45 | F-1 | 5.0 | E-1/E-2/E-3 | 2000/1200/200 |
| EXAMPLE 46 | F-1 | 5.0 | E-1/E-2/E-3 | 2000/1200/200 |
| EXAMPLE 47 | F-1 | 5.0 | E-1/E-2/E-3 | 2000/1200/200 |
| EXAMPLE 48 | F-1 | 5.0 | E-1/E-2/E-3 | 2000/1200/200 |
| EXAMPLE 49 | F-1 | 5.0 | E-1/E-2/E-3 | 2000/1200/200 |
| EXAMPLE 50 | F-1 | 5.0 | E-1/E-2/E-3 | 2000/1200/200 |
| EXAMPLE 51 | F-1 | 5.0 | E-1/E-2/E-3 | 2000/1200/200 |
| EXAMPLE 52 | F-1 | 5.0 | E-1/E-2/E-3 | 2000/1200/200 |
| EXAMPLE 53 | F-1 | 5.0 | E-1/E-2/E-3 | 2000/1200/200 |
| EXAMPLE 54 | F-1 | 5.0 | E-1/E-2/E-3 | 2000/1200/200 |
| EXAMPLE 55 | F-1 | 5.0 | E-1/E-2/E-3 | 2000/1200/200 |
| EXAMPLE 56 | F-1 | 5.0 | E-1/E-2/E-3 | 2000/1200/200 |
| EXAMPLE 57 | F-1 | 5.0 | E-1/E-2/E-3 | 2000/1200/200 |
| EXAMPLE 58 | F-1 | 5.0 | E-1/E-2/E-3 | 2000/1200/200 |
| EXAMPLE 59 | F-1 | 5.0 | E-1/E-2/E-3 | 2000/1200/200 |
| EXAMPLE 60 | F-1 | 5.0 | E-1/E-2/E-3 | 2000/1200/200 |
| EXAMPLE 61 | F-1 | 5.0 | E-1/E-2/E-3 | 2000/1200/200 |
| EXAMPLE 62 | F-1 | 5.0 | E-1/E-2/E-3 | 2000/1200/200 |
| EXAMPLE 63 | F-1 | 5.0 | E-1/E-2/E-3 | 2000/1200/200 |
| EXAMPLE 64 | F-1 | 5.0 | E-1/E-2/E-3 | 2000/1200/200 |
| EXAMPLE 65 | F-2 | 5.0 | E-1/E-2/E-3 | 2000/1200/200 |
| EXAMPLE 66 | F-3 | 5.0 | E-1/E-2/E-3 | 2000/1200/200 |
| EXAMPLE 67 | F-4 | 5.0 | E-1/E-2/E-3 | 2000/1200/200 |
| COMPARATIVE | F-1 | 5.0 | E-1/E-2/E-3 | 2000/1200/200 |
| EXAMPLE 1 | | | | |
| COMPARATIVE | F-1 | 5.0 | E-1/E-2/E-3 | 2000/1200/200 |
| EXAMPLE 2 | | | | |
| COMPARATIVE | F-1 | 5.0 | E-1/E-2/E-3 | 2000/1200/200 |
| EXAMPLE 3 | | | | |
| COMPARATIVE | F-1 | 5.0 | E-1/E-2/E-3 | 2000/1200/200 |
| EXAMPLE 4 | | | | |
| COMPARATIVE | F-1 | 5.0 | E-1/E-2/E-3 | 2000/1200/200 |
| EXAMPLE 5 | | | | |
| COMPARATIVE | F-1 | 5.0 | E-1/E-2/E-3 | 2000/1200/200 |
| EXAMPLE 6 | | | | |
| COMPARATIVE | F-1 | 5.0 | E-1/E-2/E-3 | 2000/1200/200 |
| EXAMPLE 7 | | | | |

### <Formation of Resist Pattern Using Negative Radiation-Sensitive Composition for ArF Exposure>

A composition for forming an underlayer film (“ARC66” manufactured by Brewer Science, Inc.) was applied onto a 12 inch silicon wafer using a spin coater (“CLEAN TRACK ACT12” manufactured by Tokyo Electron Limited), and then heated at 205° C. for 60 seconds to form an underlayer film having an average thickness of 100 nm. The negative radiation-sensitive composition for ArF exposure prepared above was applied onto the underlayer film using the spin coater, and subjected to PB (prebake) at 100° C. for 60 seconds. Thereafter, cooling was performed at 23° C. for 30 seconds to form a resist film having an average thickness of 110 nm. Next, this resist film was exposed through a mask pattern having 40 nm holes and 80 nm pitches with use of an ArF excimer laser immersion exposure apparatus (“TWINSCAN XT-1900i” manufactured by ASML) with NA of 1.35 under an optical condition of Dipole (σ=0.9/0.7). After the exposure, PEB (post exposure bake) was performed at 100° C. for 60 seconds. Thereafter, the resist film was developed with an organic solvent using n-butyl acetate as an organic solvent developer, and dried to form a negative resist pattern (40 nm hole, 80 nm pitch).

### <Evaluation>

The resist pattern formed using the negative radiation-sensitive composition for ArF exposure was evaluated on sensitivity, CDU performance, DOF performance, pattern circularity, and the number of development defects according to the following methods. The results are shown in the following Table 5. It is to be noted that a scanning electron microscope (“CG-5000” manufactured by Hitachi High-Tech Corporation) was used for measurement of the resist pattern.

### [Sensitivity]

An exposure dose at which a 40 nm hole and 80 nm pitch pattern was formed in formation of a resist pattern using the negative radiation-sensitive composition for ArF exposure was defined as the optimum exposure dose, and this optimum exposure dose was defined as sensitivity (mJ/cm²). In a case of being 35 mJ/cm² or less, the sensitivity was evaluated as “good”, and in a case of being more than 35 mJ/cm², the sensitivity was evaluated as “poor”.

### [CDU Performance]

A resist pattern having 40 nm holes and 80 nm pitches was measured with use of the scanning electron microscope, and measurement was performed at any 1,800 points in total from above the pattern. The dimensional variation (30) was determined and taken as the CDU performance (nm). The smaller the value of CDU performance, the smaller the variation in hole diameter in a long period, and the better the CDU performance. When the value was 3.0 nm or less, the CDU performance was evaluated as “good”, and when the value exceeded 3.0 nm, the CDU performance was evaluated as “poor”.

### [DOF Performance]

In the resist pattern resolved at the optimum exposure dose determined in the evaluation of the sensitivity, a range of focal depth (DOF) at which the diameter of the formed hole pattern was 30 nm or more and 50 nm or less was measured. In a case of being 100 nm or more, the DOF performance was evaluated as “good”, and in a case of being less than 100 nm, the DOF performance was evaluated as “poor”.

### [Pattern Circularity]

The contact holes with 40 nm holes and 80 nm pitches formed by irradiation with the optimum exposure dose determined in the evaluation of the sensitivity were observed in planar view with use of the scanning electron microscope, and the size in the longitudinal direction and the size in the lateral direction were measured. The pattern circularity was evaluated as “A” (extremely good) when the ratio of the size in the longitudinal direction to the size in the lateral direction was 0.95 or more and less than 1.05, “B” (good) when the ratio was 0.90 or more and less than 0.95, or 1.05 or more and less than 1.10, and “C” (poor) when the ratio was less than 0.90 or more than 1.10.

### [Number of Development Defects]

The resist film was exposed at the optimum exposure dose to form a contact hole pattern having 40 nm holes and 80 nm pitches, thereby obtaining a wafer for defect inspection. The number of defects on this wafer for defect inspection was measured with use of a defect inspection device (“KLA 2810” of KLA-Tencor Corporation). The defects having a diameter of 50 μm or less were determined to be derived from the resist film, and the number of the defects was calculated. When the number of the defects determined to be derived from the resist film was 50 or less, the number of defects after development was evaluated as “good”, and when more than 50, evaluated as “poor”.

TABLE 5

| | RADIATION- | | | | | NUMBER OF |
|---|---|---|---|---|---|---|
| | SENSITIVE | SENSITIVITY | CDU | DOF | PATTERN | DEVELOPMENT |
| | COMPOSITION | (mJ/cm²) | (nm) | (nm) | CIRCULARITY | DEFECTS |
| EXAMPLE 1 | J-1 | 25 | 2.1 | 180 | A | 5 |
| EXAMPLE 2 | J-2 | 28 | 1.9 | 190 | A | 4 |
| EXAMPLE 3 | J-3 | 27 | 2.0 | 200 | A | 6 |
| EXAMPLE 4 | J-4 | 28 | 2.1 | 190 | A | 2 |
| EXAMPLE 5 | J-5 | 27 | 1.8 | 170 | A | 5 |
| EXAMPLE 6 | J-6 | 24 | 2.2 | 210 | A | 3 |
| EXAMPLE 7 | J-7 | 26 | 2.0 | 190 | A | 1 |
| EXAMPLE 8 | J-8 | 27 | 2.1 | 200 | A | 0 |
| EXAMPLE 9 | J-9 | 25 | 2.0 | 210 | A | 1 |
| EXAMPLE 10 | J-10 | 27 | 1.9 | 220 | A | 4 |
| EXAMPLE 11 | J-11 | 25 | 2.0 | 190 | A | 2 |
| EXAMPLE 96 | J-96 | 23 | 2.2 | 180 | A | 5 |
| EXAMPLE 97 | J-97 | 26 | 2.0 | 170 | A | 8 |
| EXAMPLE 12 | J-12 | 25 | 2.0 | 190 | A | 1 |
| EXAMPLE 13 | J-13 | 26 | 1.9 | 180 | A | 4 |
| EXAMPLE 14 | J-14 | 26 | 1.7 | 190 | A | 5 |
| EXAMPLE 15 | J-15 | 28 | 2.1 | 200 | A | 2 |
| EXAMPLE 16 | J-16 | 25 | 2.0 | 210 | A | 8 |
| EXAMPLE 17 | J-17 | 27 | 2.1 | 190 | A | 9 |
| EXAMPLE 18 | J-18 | 22 | 2.4 | 200 | A | 3 |
| EXAMPLE 19 | J-19 | 26 | 2.1 | 210 | A | 5 |
| EXAMPLE 20 | J-20 | 27 | 2.1 | 180 | A | 7 |
| EXAMPLE 21 | J-21 | 25 | 2.0 | 190 | A | 3 |
| EXAMPLE 22 | J-22 | 26 | 1.8 | 200 | A | 7 |
| EXAMPLE 23 | J-23 | 25 | 1.9 | 210 | A | 2 |
| EXAMPLE 24 | J-24 | 27 | 2.0 | 210 | A | 8 |
| EXAMPLE 25 | J-25 | 25 | 2.1 | 190 | A | 5 |
| EXAMPLE 26 | J-26 | 26 | 2.2 | 200 | A | 7 |
| EXAMPLE 27 | J-27 | 23 | 1.9 | 210 | A | 5 |
| EXAMPLE 28 | J-28 | 24 | 1.9 | 220 | A | 7 |
| EXAMPLE 29 | J-29 | 25 | 1.7 | 190 | A | 4 |
| EXAMPLE 30 | J-30 | 26 | 2.1 | 190 | A | 0 |
| EXAMPLE 31 | J-31 | 27 | 2.0 | 180 | A | 0 |
| EXAMPLE 32 | J-32 | 24 | 1.8 | 190 | A | 4 |
| EXAMPLE 33 | J-33 | 26 | 2.2 | 190 | A | 7 |
| EXAMPLE 34 | J-34 | 27 | 2.0 | 180 | A | 3 |
| EXAMPLE 35 | J-35 | 25 | 2.1 | 190 | A | 6 |
| EXAMPLE 36 | J-36 | 26 | 1.9 | 190 | A | 8 |
| EXAMPLE 37 | J-37 | 27 | 1.9 | 180 | A | 2 |
| EXAMPLE 38 | J-38 | 28 | 1.7 | 180 | A | 8 |
| EXAMPLE 39 | J-39 | 25 | 2.1 | 170 | A | 4 |
| EXAMPLE 40 | J-40 | 25 | 2.0 | 180 | A | 8 |
| EXAMPLE 41 | J-41 | 27 | 1.8 | 180 | A | 4 |
| EXAMPLE 42 | J-42 | 25 | 2.0 | 190 | A | 3 |
| EXAMPLE 43 | J-43 | 27 | 2.1 | 190 | A | 4 |
| EXAMPLE 44 | J-44 | 28 | 2.0 | 190 | A | 9 |
| EXAMPLE 45 | J-45 | 32 | 2.6 | 130 | A | 37 |
| EXAMPLE 46 | J-46 | 33 | 2.6 | 120 | A | 36 |
| EXAMPLE 47 | J-47 | 34 | 2.7 | 110 | A | 40 |
| EXAMPLE 48 | J-48 | 31 | 2.8 | 120 | A | 32 |
| EXAMPLE 49 | J-49 | 24 | 2.1 | 200 | A | 6 |
| EXAMPLE 50 | J-50 | 26 | 2.2 | 210 | A | 3 |
| EXAMPLE 51 | J-51 | 21 | 2.0 | 190 | A | 8 |
| EXAMPLE 52 | J-52 | 26 | 2.1 | 200 | A | 9 |
| EXAMPLE 53 | J-53 | 27 | 1.7 | 180 | A | 4 |
| EXAMPLE 54 | J-54 | 26 | 1.8 | 170 | A | 6 |
| EXAMPLE 55 | J-55 | 23 | 2.0 | 170 | A | 4 |
| EXAMPLE 56 | J-56 | 26 | 1.9 | 180 | A | 2 |
| EXAMPLE 57 | J-57 | 26 | 2.1 | 180 | A | 2 |
| EXAMPLE 58 | J-58 | 22 | 2.0 | 190 | A | 1 |
| EXAMPLE 59 | J-59 | 23 | 1.8 | 200 | A | 6 |
| EXAMPLE 60 | J-60 | 27 | 1.9 | 180 | A | 0 |
| EXAMPLE 61 | J-61 | 25 | 2.0 | 190 | A | 4 |
| EXAMPLE 62 | J-62 | 26 | 2.1 | 170 | A | 6 |
| EXAMPLE 63 | J-63 | 22 | 2.5 | 120 | A | 19 |
| EXAMPLE 64 | J-64 | 27 | 2.6 | 150 | A | 9 |
| EXAMPLE 65 | J-65 | 25 | 2.0 | 190 | A | 1 |
| EXAMPLE 66 | J-66 | 25 | 2.1 | 180 | A | 9 |
| EXAMPLE 67 | J-67 | 26 | 2.0 | 180 | A | 0 |
| COMPARATIVE | CJ-1 | 40 | 4.1 | 30 | C | 121 |
| EXAMPLE 1 | | | | | | |
| COMPARATIVE | CJ-2 | 36 | 4.2 | 30 | C | 134 |
| EXAMPLE 2 | | | | | | |
| COMPARATIVE | CJ-3 | 36 | 4.3 | 40 | C | 151 |
| EXAMPLE 3 | | | | | | |
| COMPARATIVE | CJ-4 | 37 | 3.8 | 50 | C | 102 |
| EXAMPLE 4 | | | | | | |
| COMPARATIVE | CJ-5 | 36 | 3.4 | 80 | B | 67 |
| EXAMPLE 5 | | | | | | |
| COMPARATIVE | CJ-6 | 37 | 3.9 | 80 | C | 72 |
| EXAMPLE 6 | | | | | | |
| COMPARATIVE | CJ-7 | 40 | 3.8 | 70 | B | 69 |
| EXAMPLE 7 | | | | | | |

As is apparent from the results in Table 5, the radiation-sensitive compositions of Examples 1 to 67 and 96 to 97 were good in sensitivity, CDU performance, DOF performance, pattern circularity, and the number of development defects when used for ArF exposure. On the other hand, the radiation-sensitive compositions of Comparative Examples 1 to 7 were inferior in sensitivity, CDU performance, DOF performance, pattern circularity, and the number of development defects to those of Examples. Therefore, it can be said that when the radiation-sensitive compositions of Examples 1 to 67 and 96 to 97 are used for negative ArF exposure, good CDU performance, DOF performance, and pattern circularity can be exhibited while high sensitivity is maintained, and development defect suppression performance is also excellent.

### <Preparation of Positive Radiation-Sensitive Composition for ArF Exposure>

### Example 68

Mixed were 100 parts by mass of (A-1) as an [A] polymer, 10.0 parts by mass of (B-7) as a [B] radiation-sensitive acid generator, 8.0 parts by mass of (C-2) as a [C] onium salt (1), 3.0 parts by mass (solid content) of (F-2) as an [F] high fluorine-content polymer, and 3,230 parts by mass (2,200/1200/30 parts by mass) of a mixed solvent of (E-1)/(E-2)/(E-3) as an [E] solvent, followed by filtration through a membrane filter having a pore size of 0.2 μm to prepare a radiation-sensitive composition (J-68).

### Examples 69 to 81 and Comparative Examples 8 to 10

Radiation-sensitive compositions (J-69) to (J-81) and (CJ-8) to (CJ-10) were prepared in the same manner as in Example 68 except that the respective components of the types and contents shown in the following Table 6 were used.

TABLE 6

| | | | | [B] RADIATION- | | | |
|---|---|---|---|---|---|---|---|
| | | | | SENSITIVE ACID | | | |
| | | [A] POLYMER | | GENERATOR | | [C] ONIUM SALT (1) | |
| | | | CONTENT | | CONTENT | | CONTENT |
| | RADIATION- | | (PARTS | | (PARTS | | (PARTS |
| | SENSITIVE | | BY | | BY | | BY |
| | COMPOSITION | TYPE | MASS) | TYPE | MASS) | TYPE | MASS) |
| EXAMPLE 68 | J-68 | A-1 | 100 | B-7 | 10.0 | C-2 | 8.0 |
| EXAMPLE 69 | J-69 | A-6 | 100 | B-7 | 10.0 | C-2 | 8.0 |
| EXAMPLE 70 | J-70 | A-7 | 100 | B-7 | 10.0 | C-2 | 8.0 |
| EXAMPLE 71 | J-71 | A-1 | 100 | B-7 | 10.0 | C-9 | 6.0 |
| EXAMPLE 72 | J-72 | A-1 | 100 | B-7 | 10.0 | C-10 | 6.0 |
| EXAMPLE 73 | J-73 | A-1 | 100 | B-7 | 10.0 | C-16 | 6.0 |
| EXAMPLE 74 | J-74 | A-1 | 100 | B-7 | 10.0 | C-18 | 6.0 |
| EXAMPLE 75 | J-75 | A-1 | 100 | B-7 | 10.0 | C-24 | 6.0 |
| EXAMPLE 76 | J-76 | A-1 | 100 | B-7 | 10.0 | C-29 | 6.0 |
| EXAMPLE 77 | J-77 | A-1 | 100 | B-7 | 10.0 | C-13/C-23 | 3.0/3.0 |
| EXAMPLE 78 | J-78 | A-1 | 100 | B-2 | 10.0 | C-2 | 8.0 |
| EXAMPLE 79 | J-79 | A-1 | 100 | B-3 | 10.0 | C-2 | 8.0 |
| EXAMPLE 80 | J-80 | A-1 | 100 | B-5 | 10.0 | C-2 | 8.0 |
| EXAMPLE 81 | J-81 | A-1 | 100 | B-9 | 10.0 | C-2 | 8.0 |
| COMPARATIVE | CJ-8 | A-1 | 100 | B-7 | 10.0 | cc-1 | 8.0 |
| EXAMPLE 8 | | | | | | | |
| COMPARATIVE | CJ-9 | A-1 | 100 | B-7 | 10.0 | cc-2 | 8.0 |
| EXAMPLE 9 | | | | | | | |
| COMPARATIVE | CJ-10 | A-1 | 100 | B-7 | 10.0 | cc-4 | 8.0 |
| EXAMPLE 10 | | | | | | | |

| | [F] HIGH FLUORINE- | | | |
|---|---|---|---|---|
| | CONTENT POLYMER | | [E] SOLVENT | |
| | | CONTENT | | CONTENT |
| | | (PARTS | | (PARTS |
| | | BY | | BY |
| | TYPE | MASS) | TYPE | MASS) |
| EXAMPLE 68 | F-2 | 3.0 | E-1/E-2/E-3 | 2000/1200/30 |
| EXAMPLE 69 | F-2 | 3.0 | E-1/E-2/E-3 | 2000/1200/30 |
| EXAMPLE 70 | F-2 | 3.0 | E-1/E-2/E-3 | 2000/1200/30 |
| EXAMPLE 71 | F-2 | 3.0 | E-1/E-2/E-3 | 2000/1200/30 |
| EXAMPLE 72 | F-2 | 3.0 | E-1/E-2/E-3 | 2000/1200/30 |
| EXAMPLE 73 | F-2 | 3.0 | E-1/E-2/E-3 | 2000/1200/30 |
| EXAMPLE 74 | F-2 | 3.0 | E-1/E-2/E-3 | 2000/1200/30 |
| EXAMPLE 75 | F-2 | 3.0 | E-1/E-2/E-3 | 2000/1200/30 |
| EXAMPLE 76 | F-2 | 3.0 | E-1/E-2/E-3 | 2000/1200/30 |
| EXAMPLE 77 | F-2 | 3.0 | E-1/E-2/E-3 | 2000/1200/30 |
| EXAMPLE 78 | F-2 | 3.0 | E-1/E-2/E-3 | 2000/1200/30 |
| EXAMPLE 79 | F-2 | 3.0 | E-1/E-2/E-3 | 2000/1200/30 |
| EXAMPLE 80 | F-2 | 3.0 | E-1/E-2/E-3 | 2000/1200/30 |
| EXAMPLE 81 | F-2 | 3.0 | E-1/E-2/E-3 | 2000/1200/30 |
| COMPARATIVE | F-2 | 3.0 | E-1/E-2/E-3 | 2000/1200/30 |
| EXAMPLE 8 | | | | |
| COMPARATIVE | F-2 | 3.0 | E-1/E-2/E-3 | 2000/1200/30 |
| EXAMPLE 9 | | | | |
| COMPARATIVE | F-2 | 3.0 | E-1/E-2/E-3 | 2000/1200/30 |
| EXAMPLE 10 | | | | |

### <Formation of Resist Pattern Using Positive Radiation-Sensitive Composition for ArF Exposure>

Onto the surface of a 12-inch silicon wafer, an underlayer film forming composition (“ARC66” manufactured by Brewer Science Incorporated.) was applied with use of a spin coater (“CLEAN TRACK ACT12” manufactured by Tokyo Electron Limited.). The wafer was then heated at 205° C. for 60 seconds to form an underlayer film having an average thickness of 100 nm. The positive radiation-sensitive composition for ArF exposure as prepared above was applied onto the underlayer film with use of the spin coater, followed by PB (pre-baking) at 100° C. for 60 seconds. Thereafter, cooling was performed at 23° C. for 30 seconds to form a resist film having an average thickness of 120 nm. Next, the resist film was exposed through a 60 nm line-and-space mask pattern with use of an ArF excimer laser immersion exposure apparatus (“TWINSCAN XT-1900i” manufactured by ASML) with NA of 1.35 under an optical condition of Dipole (σ=0.9/0.7). After the exposure, PEB (post exposure bake) was performed at 100° C. for 60 seconds. Thereafter, the resist film was subjected to alkaline development using a 2.38 mass % aqueous TMAH solution as an alkaline developer, and after the development, the resist film was washed with water and further dried to form a positive resist pattern (60 nm line-and-space pattern).

### <Evaluation>

The resist pattern formed using the positive radiation-sensitive composition for ArF exposure was evaluated on sensitivity, LWR performance, and pattern rectangularity in accordance with the following methods. The results are shown in the following Table 7. A scanning electron microscope (“CG-5000” manufactured by Hitachi High-Tech Corporation) was used for measurement of the resist pattern.

### [Sensitivity]

An exposure dose at which a 60 nm line-and-space pattern was formed in formation of a resist pattern using the positive radiation-sensitive composition for ArF exposure was defined as the optimum exposure dose, and this optimum exposure dose was defined as sensitivity (mJ/cm²). In a case of being 30 mJ/cm² or less, the sensitivity was evaluated as “good”, and in a case of being more than 30 mJ/cm², the sensitivity was evaluated as “poor”.

### [LWR Performance]

A 60 nm line-and-space resist pattern was formed by irradiation with the optimum exposure dose determined in the evaluation of the sensitivity. The formed resist pattern was observed from above the pattern with use of the scanning electron microscope. The variation in the line width was measured at a total of 500 points. The 3 sigma value was determined from the distribution of the measurement values, and defined as LWR performance (nm). A smaller value of LWR indicates smaller roughness of the line and better performance. The LWR performance was evaluated as “good” when the LWR was 3.0 nm or less, and was evaluated as “poor” when the LWR exceeded 3.0 nm.

### [Pattern Rectangularity]

The 60 nm line-and-space resist pattern formed by irradiation with the optimum exposure dose determined in the evaluation of the sensitivity was observed with use of the scanning electron microscope, and the sectional shape of the line-and-space pattern was evaluated. The rectangularity of the resist pattern was evaluated as “A” (extremely good) when the ratio of the length of the lower side to the length of the upper side in the sectional shape was 1.00 or more and 1.05 or less, “B” (good) when the ratio was more than 1.05 and 1.10 or less, and “C” (poor) when the ratio was more than 1.10.

TABLE 7

| | RADIATION- | SENSI- | | PATTERN |
|---|---|---|---|---|
| | SENSITIVE | TIVITY | LWR | RECTANGU- |
| | COMPOSITION | (mJ/cm²) | (nm) | LARITY |
| EXAMPLE 68 | J-68 | 22 | 2.3 | A |
| EXAMPLE 69 | J-69 | 21 | 2.4 | A |
| EXAMPLE 70 | J-70 | 24 | 2.1 | A |
| EXAMPLE 71 | J-71 | 22 | 2.4 | A |
| EXAMPLE 72 | J-72 | 24 | 2.3 | A |
| EXAMPLE 73 | J-73 | 23 | 2.6 | A |
| EXAMPLE 74 | J-74 | 25 | 2.3 | A |
| EXAMPLE 75 | J-75 | 22 | 2.3 | A |
| EXAMPLE 76 | J-76 | 21 | 2.1 | A |
| EXAMPLE 77 | J-77 | 22 | 2.4 | A |
| EXAMPLE 78 | J-78 | 24 | 2.5 | A |
| EXAMPLE 79 | J-79 | 25 | 2.1 | A |
| EXAMPLE 80 | J-80 | 26 | 2.3 | A |
| EXAMPLE 81 | J-81 | 23 | 2.1 | A |
| COMPARATIVE | CJ-8 | 34 | 3.8 | C |
| EXAMPLE 8 | | | | |
| COMPARATIVE | CJ-9 | 31 | 3.6 | C |
| EXAMPLE 9 | | | | |
| COMPARATIVE | CJ-10 | 32 | 3.5 | C |
| EXAMPLE 10 | | | | |

As is apparent from the results in Table 7, the radiation-sensitive compositions of Examples 68 to 81 were good in all of sensitivity, LWR performance, and pattern rectangularity when used for forming a positive resist pattern by ArF exposure. On the other hand, the radiation-sensitive compositions of Comparative Examples 8 to 10 were inferior in each characteristic to that of Examples.

### <Preparation of Positive Radiation-Sensitive Composition for Extreme Ultraviolet (EUV) Exposure>

### Example 82

Mixed were 100 parts by mass of (A-12) as an [A] polymer, 30.0 parts by mass of (B-3) as a [B] radiation-sensitive acid generator, 20.0 parts by mass of (C-3) as a [C] onium salt (1), 6.0 parts by mass (solid content) of (F-5) as an [F] high fluorine-content polymer, and 6, 100 parts by mass (2,000/4,000/100 (parts by mass)) of a mixed solvent of (E-1)/(E-2)/(E-4) as an [E] solvent, followed by filtration through a membrane filter having a pore size of 0.2 μm to prepare a radiation-sensitive composition (J-82).

### Examples 83 to 94 and Comparative Examples 11 to 13

Radiation-sensitive compositions (J-83) to (J-94) and (CJ-11) to (CJ-13) were prepared in the same manner as in Example 83 except that the respective components of the types and contents shown in the following Table 8 were used.

TABLE 8

| | | | | [B] RADIATION- | | | |
|---|---|---|---|---|---|---|---|
| | | | | SENSITIVE ACID | | [C] ONIUM SALT | |
| | | [A] POLYMER | | GENERATOR | | (1) | |
| | | | CONTENT | | CONTENT | | CONTENT |
| | RADIATION- | | (PARTS | | (PARTS | | (PARTS |
| | SENSITIVE | | BY | | BY | | BY |
| | COMPOSITION | TYPE | MASS) | TYPE | MASS) | TYPE | MASS) |
| EXAMPLE 82 | J-82 | A-12 | 100 | B-3 | 30.0 | C-3 | 20.0 |
| EXAMPLE 83 | J-83 | A-13 | 100 | B-3 | 30.0 | C-3 | 20.0 |
| EXAMPLE 84 | J-84 | A-14 | 100 | B-3 | 30.0 | C-3 | 20.0 |
| EXAMPLE 85 | J-85 | A-15 | 100 | B-3 | 30.0 | C-3 | 20.0 |
| EXAMPLE 86 | J-86 | A-13 | 100 | B-3 | 30.0 | C-5 | 20.0 |
| EXAMPLE 87 | J-87 | A-13 | 100 | B-3 | 30.0 | C-8 | 20.0 |
| EXAMPLE 88 | J-88 | A-13 | 100 | B-3 | 30.0 | C-17 | 20.0 |
| EXAMPLE 89 | J-89 | A-13 | 100 | B-3 | 30.0 | C-22 | 20.0 |
| EXAMPLE 90 | J-90 | A-13 | 100 | B-3 | 30.0 | C-27 | 20.0 |
| EXAMPLE 91 | J-91 | A-13 | 100 | B-3 | 30.0 | C-29 | 20.0 |
| EXAMPLE 92 | J-92 | A-13 | 100 | B-3 | 30.0 | C-30 | 20.0 |
| EXAMPLE 93 | J-93 | A-13 | 100 | B-4 | 30.0 | C-3 | 20.0 |
| EXAMPLE 94 | J-94 | A-13 | 100 | B-8 | 30.0 | C-3 | 20.0 |
| COMPARATIVE | CJ-11 | A-13 | 100 | B-3 | 10.0 | cc-1 | 20.0 |
| EXAMPLE 11 | | | | | | | |
| COMPARATIVE | CJ-12 | A-13 | 100 | B-3 | 10.0 | cc-2 | 20.0 |
| EXAMPLE 12 | | | | | | | |
| COMPARATIVE | CJ-13 | A-13 | 100 | B-3 | 10.0 | cc-4 | 20.0 |
| EXAMPLE 13 | | | | | | | |

| | [F] HIGH FLUORINE- | | | |
|---|---|---|---|---|
| | CONTENT POLYMER | | [E] SOLVENT | |
| | | CONTENT | | CONTENT |
| | | (PARTS | | (PARTS |
| | | BY | | BY |
| | TYPE | MASS) | TYPE | MASS) |
| EXAMPLE 82 | F-5 | 6.0 | E-1/E-2/E-4 | 2000/4000/100 |
| EXAMPLE 83 | F-5 | 6.0 | E-1/E-2/E-4 | 2000/4000/100 |
| EXAMPLE 84 | F-5 | 6.0 | E-1/E-2/E-4 | 2000/4000/100 |
| EXAMPLE 85 | F-5 | 6.0 | E-1/E-2/E-4 | 2000/4000/100 |
| EXAMPLE 86 | F-5 | 6.0 | E-1/E-2/E-4 | 2000/4000/100 |
| EXAMPLE 87 | F-5 | 6.0 | E-1/E-2/E-4 | 2000/4000/100 |
| EXAMPLE 88 | F-5 | 6.0 | E-1/E-2/E-4 | 2000/4000/100 |
| EXAMPLE 89 | F-5 | 6.0 | E-1/E-2/E-4 | 2000/4000/100 |
| EXAMPLE 90 | F-5 | 6.0 | E-1/E-2/E-4 | 2000/4000/100 |
| EXAMPLE 91 | F-5 | 6.0 | E-1/E-2/E-4 | 2000/4000/100 |
| EXAMPLE 92 | F-5 | 6.0 | E-1/E-2/E-4 | 2000/4000/100 |
| EXAMPLE 93 | F-5 | 6.0 | E-1/E-2/E-4 | 2000/4000/100 |
| EXAMPLE 94 | F-5 | 6.0 | E-1/E-2/E-4 | 2000/4000/100 |
| COMPARATIVE | F-5 | 6.0 | E-1/E-2/E-4 | 2000/4000/100 |
| EXAMPLE 11 | | | | |
| COMPARATIVE | F-5 | 6.0 | E-1/E-2/E-4 | 2000/4000/100 |
| EXAMPLE 12 | | | | |
| COMPARATIVE | F-5 | 6.0 | E-1/E-2/E-4 | 2000/4000/100 |
| EXAMPLE 13 | | | | |

### <Formation of Resist Pattern Using Positive Radiation-Sensitive Composition for EUV Exposure>

Onto the surface of a 12-inch silicon wafer, an underlayer film forming composition (“ARC66” manufactured by Brewer Science Incorporated.) was applied with use of a spin coater (“CLEAN TRACK ACT12” manufactured by Tokyo Electron Limited.). The wafer was then heated at 205° C. for 60 seconds to form an underlayer film having an average thickness of 105 nm. The positive radiation-sensitive composition for EUV exposure as prepared above was applied onto the underlayer film with use of the spin coater, followed by PB at 130° C. for 60 seconds. Thereafter, cooling was performed at 23° C. for 30 seconds to form a resist film having an average thickness of 50 nm. Subsequently, this resist film was exposed with an EUV exposure apparatus (“NXE3300” manufactured by ASML Holding N.V.) with an NA of 0.33 under an illumination condition of conventional illumination (s=0.89), and with a mask of imecDEFECT32FFR02. After the exposure, PEB was performed at 120° C. for 60 seconds. Thereafter, the resist film was subjected to alkaline development using a 2.38 mass % aqueous TMAH solution as an alkaline developer, and after the development, the resist film was washed with water and further dried to form a positive resist pattern (25 nm line-and-space pattern).

### <Evaluation>

The sensitivity, LWR performance, and pattern rectangularity of each of resist patterns formed using the positive radiation-sensitive compositions for EUV exposure were evaluated according to the following methods. The results are shown in the following Table 9. It is to be noted that a scanning electron microscope (“CG-5000” manufactured by Hitachi High-Tech Corporation) was used for measurement of the resist pattern.

### [Sensitivity]

In formation of the resist pattern using the positive radiation-sensitive composition for EUV exposure, an exposure dose at which a 25 nm line-and-space pattern was formed was defined as an optimum exposure dose, and this optimum exposure dose was defined as sensitivity (mJ/cm²). A case where the sensitivity was 50 mJ/cm² or less was evaluated as “good”, and a case where the sensitivity exceeded 50 mJ/cm² was evaluated as “poor”.

### [LWR Performance]

A resist pattern was formed with the mask size adjusted so as to form a 25 nm line-and-space pattern by irradiation with the optimum exposure dose obtained in the evaluation of the sensitivity. The formed resist pattern was observed from above the pattern using the scanning electron microscope. The variation in line width was measured at 500 points in total, the value of 30 was obtained from the distribution of the measured values, and the value of 30 was defined as LWR (nm). A smaller value of LWR indicates smaller displacement of the line and better performance. A case where the LWR performance was 3.0 nm or less was evaluated as “good”, and a case where the LWR performance exceeded 3.0 nm was evaluated as “poor”.

### [Pattern Rectangularity]

The 25 nm line-and-space resist pattern formed by irradiation with the optimum exposure dose determined in the evaluation of the sensitivity was observed with use of the scanning electron microscope, and the sectional shape of the line-and-space pattern was evaluated. The rectangularity of the resist pattern was evaluated as “A” (extremely good) when the ratio of the length of the lower side to the length of the upper side in the sectional shape was 1.00 or more and 1.05 or less, “B” (good) when the ratio was more than 1.05 and 1.10 or less, and “C” (poor) when the ratio was more than 1.10.

TABLE 9

| | RADIATION- | SENSI- | | PATTERN |
|---|---|---|---|---|
| | SENSITIVE | TIVITY | LWR | RECTANGU- |
| | COMPOSITION | (mJ/cm²) | (nm) | LARITY |
| EXAMPLE 82 | J-82 | 44 | 2.5 | A |
| EXAMPLE 83 | J-83 | 42 | 2.1 | A |
| EXAMPLE 84 | J-84 | 40 | 2.3 | A |
| EXAMPLE 85 | J-85 | 43 | 2.1 | A |
| EXAMPLE 86 | J-86 | 44 | 2.2 | A |
| EXAMPLE 87 | J-87 | 45 | 2.4 | A |
| EXAMPLE 88 | J-88 | 46 | 2.5 | A |
| EXAMPLE 89 | J-89 | 42 | 2.6 | A |
| EXAMPLE 90 | J-90 | 43 | 2.3 | A |
| EXAMPLE 91 | J-91 | 45 | 2.3 | A |
| EXAMPLE 92 | J-92 | 42 | 2.4 | A |
| EXAMPLE 93 | J-93 | 42 | 2.2 | A |
| EXAMPLE 94 | J-94 | 44 | 2.4 | A |
| COMPARATIVE | CJ-11 | 55 | 3.4 | C |
| EXAMPLE 11 | | | | |
| COMPARATIVE | CJ-12 | 56 | 4.1 | C |
| EXAMPLE 12 | | | | |
| COMPARATIVE | CJ-13 | 52 | 3.7 | C |
| EXAMPLE 13 | | | | |

As is apparent from the results in Table 9, the radiation-sensitive compositions of Examples 82 to 94 were good in all of sensitivity, LWR performance, and pattern rectangularity when used for forming a resist pattern by EUV exposure. On the other hand, the radiation-sensitive compositions of Comparative Examples 11 to 13 were inferior in each characteristic to that of Examples.

<Preparation of Negative Radiation-Sensitive Composition for EUV Exposure, Formation of Resist Pattern Using this Composition, and Evaluation>

### Example 95

Mixed were 100 parts by mass of (A-15) as an [A] polymer, 40.0 parts by mass of (B-4) as a [B] radiation-sensitive acid generator, 35.0 parts by mass of (C-17) as a [C] onium salt (1), 3.0 parts by mass (solid content) of (F-5) as an [F] high fluorine-content polymer, and 6,110 parts by mass (4,280/1,830 (parts by mass)) of a mixed solvent of (E-2)/(E-4) as an [E] solvent, followed by filtration through a membrane filter having a pore size of 0.2 μm to prepare a radiation-sensitive composition (J-95).

Onto the surface of a 12-inch silicon wafer, an underlayer film forming composition (“ARC66” manufactured by Brewer Science Incorporated.) was applied with use of a spin coater (“CLEAN TRACK ACT12” manufactured by Tokyo Electron Limited.). The wafer was then heated at 205° C. for 60 seconds to form an underlayer film having an average thickness of 105 nm. The radiation-sensitive composition (J-95) as prepared above was applied onto the underlayer film with use of the spin coater, followed by PB at 130° C. for 60 seconds. Thereafter, cooling was performed at 23° C. for 30 seconds to form a resist film having an average thickness of 45 nm. Next, the resist film was exposed with use of an EUV exposure apparatus (“NXE3300”, manufactured by ASML) with NA of 0.33 under a lighting condition of Conventional s=0.89 and with a mask of imecDEFECT32FFR15. After the exposure, PEB was performed at 120° C. for 60 seconds. Thereafter, the resist film was developed with an organic solvent using n-butyl acetate as an organic solvent developer, and dried to form a negative resist pattern (20 nm hole, 40 nm pitch).

The resist pattern formed using the radiation-sensitive composition (J-95) was evaluated on sensitivity and CDU performance in the same manner as in the evaluation of the resist pattern formed using the negative radiation-sensitive composition for ArF immersion exposure. As a result, the radiation-sensitive composition of Example 95 had good sensitivity and CDU performance even when a negative resist pattern was formed by EUV exposure.

According to the radiation-sensitive composition, the pattern forming method, and the onium salt described above, a resist pattern having good sensitivity to exposure light and excellent CDU performance, DOF performance, pattern circularity, LWR performance, pattern rectangularity, and development defect suppression performance can be formed. Therefore, the composition and method can be suitably used for a machining process and the like of a semiconductor device that is expected to be further miniaturized in the future.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A radiation-sensitive composition comprising:
an onium salt represented by formula (1);
a polymer comprising a structural unit (I) which comprises an acid-dissociable group; and
a solvent: 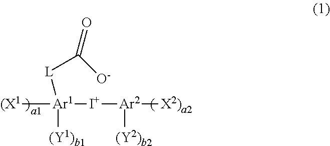
wherein in the formula (1),
Ar¹ is an (a1+b1+1)-valent aromatic ring,
Ar² is an (a2+b2+1)-valent aromatic ring,
X¹ and X² are each independently a monovalent organic group having 1 to 20 carbon atoms, a cyano group, a nitro group, or a halogen atom, when a plurality of X¹s and X²s are present, the plurality of X¹s and X²s are identical to or different from each other,
Y¹ is a monovalent organic group having 4 to 20 carbon atoms bonded to Ar¹ through —O—, —S—, or —SO₂—, or a monovalent perfluoroalkyl group having 1 to 20 carbon atoms, when a plurality of Y¹s are present, the plurality of Y¹s are identical to or different from each other,
Y² is a monovalent organic group having 4 to 20 carbon atoms bonded to Ar² through —O—, —S—, or —SO₂—, or a monovalent perfluoroalkyl group having 1 to 20 carbon atoms, when a plurality of Y²s are present, the plurality of Y²s are identical to or different from each other,
L is a single bond or a divalent linking group having 1 to 5 carbon atoms, and
a1, a2, b1, and b2 are each independently an integer of 0 to 5, provided that when the aromatic ring of Ar² is a benzene ring, b1+b2≥1.

2. The radiation-sensitive composition according to claim 1, wherein the onium salt is represented by formula (1-1), (1-2), or (1-3): 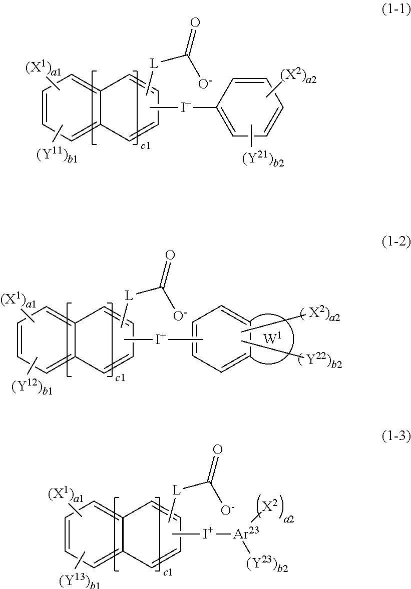
wherein in the formula (1-1), L, X¹, X², a1, a2, b1, and b2 are each as defined in the formula (1), Y¹¹ and Y²¹ are each independently a monovalent organic group having 4 to 20 carbon atoms bonded to the aromatic ring in the formula (1-1) through —O—, —S—, or —SO₂—, or a monovalent perfluoroalkyl group having 1 to 20 carbon atoms, and c1 is 0 or 1,
in the formula (1-2), L, X¹, X², a1, and a2 are each as defined in the formula (1), W¹ is an alicyclic hydrocarbon structure, an aromatic hydrocarbon structure, or an aliphatic heterocyclic structure each forming a fused ring with an adjacent benzene ring in the formula (1-2), Y¹² and Y²² are each independently a monovalent organic group having 4 to 20 carbon atoms bonded to the aromatic ring in the formula (1-2) through —O—, —S—, or —SO₂—, or a monovalent perfluoroalkyl group having 1 to 20 carbon atoms, b1 and b2 are each independently an integer of 0 to 5, and c1 is 0 or 1, and
in the formula (1-3), L, X¹, X², a1, and a2 are each as defined in the formula (1), Ar²³ is an aromatic heterocyclic ring, Y¹³ is a monovalent organic group having 4 to 20 carbon atoms bonded to the aromatic ring in the formula (1-3) through —O—, —S—, or —SO₂—, or a monovalent perfluoroalkyl group having 1 to 20 carbon atoms, Y²³ is a monovalent organic group having 4 to 20 carbon atoms bonded to Ar²³ through —O—, —S—, or —SO₂—, or a monovalent perfluoroalkyl group having 1 to 20 carbon atoms, b1 and b2 are each independently an integer of 0 to 5, and c1 is 0 or 1.

3. The radiation-sensitive composition according to claim 1, wherein Y¹ is a monovalent organic group having 4 to 20 carbon atoms bonded to Ar¹ through —O—, or a monovalent perfluoroalkyl group having 1 to 20 carbon atoms, and Y² is a monovalent organic group having 4 to 20 carbon atoms bonded to Ar² through —O—, or a monovalent perfluoroalkyl group having 1 to 20 carbon atoms.

4. The radiation-sensitive composition according to claim 1, wherein the Ar¹ is a benzene ring.

5. The radiation-sensitive composition according to claim 1, wherein L is a single bond and is bonded to an ortho position of a carbon atom to which I⁺ in the formula (1) is bonded.

6. The radiation-sensitive composition according to claim 1, wherein a content of the onium salt in the radiation-sensitive composition is 0.1 parts by mass or more and 80 parts by mass or less with respect to 100 parts by mass of the polymer.

7. The radiation-sensitive composition according to claim 1, wherein the structural unit (I) is represented by formula (3) below: 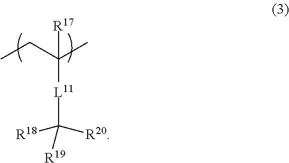
wherein in the formula (3), R¹⁷ is a hydrogen atom, a fluorine atom, a methyl group, or a trifluoromethyl group,
R¹⁸ is a substituted or unsubstituted monovalent hydrocarbon group having 1 to 20 carbon atoms,
R¹⁹ and R²⁰ are each independently a substituted or unsubstituted monovalent chain hydrocarbon group having 1 to 10 carbon atoms or a substituted or unsubstituted monovalent alicyclic hydrocarbon group having 3 to 20 carbon atoms, or R¹⁹ and R²⁰ taken together represent a divalent alicyclic group having 3 to 20 carbon atoms together with the carbon atom to which R¹⁹ and R²⁰ are bonded,
L¹¹ represents *—COO—, *-L^{11a}COO—, or *—COOL^{11a}COO—, L^{11a} is a substituted or unsubstituted alkanediyl group or arenediyl group, and * is a bond to a carbon atom bonded to R¹⁷.

8. The radiation-sensitive composition according to claim 1, wherein a content ratio of the structural unit (I) in the polymer to all structural units constituting the polymer is 5 mol % or more and 80 mol % or less.

9. The radiation-sensitive composition according to claim 1, wherein the polymer further comprises a structural unit (II) comprising at least one selected from the group consisting of a lactone structure, a cyclic carbonate structure, and a sultone structure.

10. The radiation-sensitive composition according to claim 9, wherein a content ratio of the structural unit (II) in the polymer to all structural units constituting the polymer is 5 mol % or more and 80 mol % or less.

11. The radiation-sensitive composition according to claim 1, further comprising a radiation-sensitive acid generator that is capable of generating an acid having a pKa lower than a pKa of an acid generated from the onium salt by irradiation with radiation.

12. A method for forming a pattern, comprising
directly or indirectly applying the radiation-sensitive composition according to claim 1 to a substrate to form a resist film;
exposing the resist film to light; and
developing the exposed resist film with a developer.

13. The method for forming a pattern according to claim 12, wherein exposing comprises exposing the resist film to an ArF excimer laser or extreme ultraviolet rays.

14. An onium salt represented by formula (1): 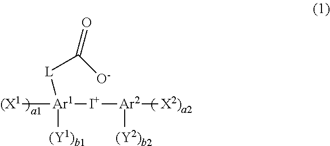
wherein in the formula (1),
Ar¹ is an (a1+b1+1)-valent aromatic ring,
Ar² is an (a2+b2+1)-valent aromatic ring,
X¹ and X² are each independently a monovalent organic group having 1 to 20 carbon atoms, a cyano group, a nitro group, or a halogen atom, when a plurality of X¹s and X²s are present, the plurality of X¹s and X²s are identical to or different from each other,
Y¹ is a monovalent organic group having 4 to 20 carbon atoms bonded to Ar¹ through —O—, —S—, or —SO₂—, or a monovalent perfluoroalkyl group having 1 to 20 carbon atoms, when a plurality of Y¹s are present, the plurality of Y¹s are identical to or different from each other,
Y² is a monovalent organic group having 4 to 20 carbon atoms bonded to Ar² through —O—, —S—, or —SO₂—, or a monovalent perfluoroalkyl group having 1 to 20 carbon atoms, when a plurality of Y²s are present, the plurality of Y²s are identical to or different from each other,
L is a single bond or a divalent linking group having 1 to 5 carbon atoms, and
a1, a2, b1, and b2 are each independently an integer of 0 to 5, provided that when the aromatic ring of Ar² is a benzene ring, b1+b2≥1.
